(19) United States
(12) Patent Application Publication
(10) Pub. No.: US 2017/0113934 A1
(43) Pub. Date: Apr. 27, 2017

(54) HETEROATOM-ENRICHED PARTIALLY-GRAPHITIC NANO-CARBONS

(71) Applicant: CARNEGIE MELLON UNIVERSITY, Pittsburgh, PA (US)

(72) Inventors: Tomasz Kowalewski, Pittsburgh, PA (US); Mingjiang Zhong, New Haven, CT (US); Eric Gottlieb, Pittsburgh, PA (US); Maciej Kopec, Pittsburgh, PA (US); Jacob Mohin, Pittsburgh, PA (US); Krzysztof Matyjaszewski, Pittsburgh, PA (US)

(21) Appl. No.: 15/191,918

(22) Filed: Jun. 24, 2016

Related U.S. Application Data
(63) Continuation-in-part of application No. 13/390,470, filed on Apr. 10, 2012, now abandoned.
(60) Provisional application No. 61/274,401, filed on Aug. 17, 2009.
(60) Provisional application No. 62/231,167, filed on Jun. 26, 2015.

(51) Int. Cl. C01B 31/00; H01L 51/00; H01G 9/20; H01L 51/44

(52) U.S. Cl. CPC C01B 31/0446; H01G 9/2031; H01G 9/2059; H01G 9/2022; H01L 51/441; H01L 51/0072; B82Y 40/00

(57) ABSTRACT

Carbon-based nanomaterials comprising graphitic domains that are doped with heteroatoms are disclosed. Processes for the production the nanomaterials, methods of using the nanomaterials, and articles or devices comprising the nanomaterials are also disclosed.

### CROSS-REFERENCE TO RELATED APPLICATIONS

This patent application is a continuation-in-part and claims the benefit of the filing date under 35 U.S.C. §120 of prior co-pending U.S. patent application Ser. No. 13/390,470. U.S. patent application Ser. No. 13/390,470 entered the United States national phase under 35 U.S.C. §371 on Apr. 10, 2012 from International Patent Application No. PCT/US2010/002257, which was filed on Aug. 17, 2010. International Patent Application No. PCT/US2010/002257 claims priority to U.S. Provisional Patent Application No. 61/274,401, which was filed on Aug. 17, 2009.

This patent application also claims priority to U.S. Provisional Patent Application No. 62/231,167, which was filed on Jun. 26, 2015.

U.S. Provisional Patent Application No. 62/231,167 (as filed) is incorporated by reference into this specification. U.S. Provisional Patent Application No. 61/274,401 (as filed) is incorporated by reference into this specification. International Patent Application No. PCT/US2010/002257 (as filed and published as WO 2011/022050A1) is incorporated by reference into this specification. U.S. patent application Ser. No. 13/390,470 (as filed and published as US 2012/0213986 A1) is incorporated by reference into this specification.

### STATEMENT REGARDING FEDERALLY SPONSORED RESEARCH OR DEVELOPMENT

This invention was made with government support under DMR0304508 and DMR0969301 awarded by the National Science Foundation. The government has certain rights in the invention.

### TECHNICAL FIELD

The present invention relates to the field of carbon-based materials, more particularly carbon-based nanomaterials, processes for producing carbon-based nanomaterials, and devices comprising carbon-based nanomaterials.

### BACKGROUND

The chemical diversity and broad utility of carbon materials arise from the great variety of solid-state forms that the solid material can assume. The possibility to synthesize materials with different contents of sp² and sp³ hybridized species, and different morphologies and/or levels of crystalline order, opens the way to engineer an extremely wide range of carbonaceous materials covering numerous areas of applications, such as faradaic processes boosting charge storage density in supercapacitors, and in electro-catalysis of industrially- and/or environmentally-important reduction reactions such as oxygen reduction reactions (ORR), hydrogen evolution reactions (HER), CO₂ reductions, sequestration of metals, and electrochemical processes for improving power density in lithium batteries.

The two dominant current routes to carbon materials can be collectively summarized as: (1) pyrolysis of organic precursors (mostly polymeric) under inert atmosphere and (2) vapor deposition techniques such as (i) physical vapor deposition (PVD) from carbon-containing gas phases and (ii) chemical vapor deposition (CVD) from hydrocarbon-containing gases. The first group of methods are used for large-scale production of commodity and engineering carbon materials utilizing such precursors as hydrocarbon gases, pitches (including petroleum, coal, coal tar, coal chars, mesophase pitch, and the like), and polymers, such as polyacrylonitrile (PAN), phenolic and furan resins, polyimides and biomass. (Carbon Materials for Advanced Technologies, Pergamon, Amsterdam, 1999; 1-33). The resulting materials contain predominantly graphitic microstructures and disordered graphitic species. Some of the most widely known applications for commodity carbon materials include fillers, carbon blacks for tire industry, activated carbons, and carbon fibers. (Carbon 1985, 23, 255-262). Owing to their good thermal and electrical conductivities, low density, good corrosion resistance, low thermal expansion and high purity and relatively low cost, engineering carbons are also widely used in electrochemistry, and in industrial applications as electrodes for steel arc furnaces and brushes for electric motors. (Carbon: electrochemical and physicochemical properties. Wiley: New York, 1988).

Highly graphitic carbon fibers can be contrasted with glassy (vitreous) carbon, a low-density, microporous material (reaching only ˜⅔ of graphite density) obtained by pyrolysis of thermosetting resins such as phenol formaldehyde or phenol furfural formaldehyde resin. (J. Mater. Sci. 2002, 37, 1-28). According to one of the models (Nature 1971, 231, 175-6), such glassy carbons possess macro-isotropic, microcrystalline structure, consisting of entangled, narrow graphitic stacks, templated after the random orientation of polymer chains in the glassy, cross-linked precursor. Importantly, the micropores of glassy carbon are closed, which renders it very chemically inert and makes it particularly suitable for aggressive environments.

Currently, there is increasing levels of interest in graphene, a substance composed of pure carbon with atoms arranged in a regular hexagonal pattern similar to graphite, but in a one-atom thick sheet. This interest is largely driven by its unique electronic properties. (Science 2009, 323, 610-613; Science 2009, 324, 1530; Angew. Chem. Int. Ed. 2009, 48, 7752-7777; J. Mater. Chem. 2009, 19, 2457-2469; Chem. Rev. 2009, 110, 132-145). The potential of graphene as an electronic component lies in its charge carrying properties, with charge carriers traveling thousands of interatomic distances without scattering, up to 0.3 μm at 300 K. (Science 2007, 315, 1379-1379]). This leads to extraordinarily high mobility surpassing silicon, and exceeding 15,000 cm² V⁻¹ s⁻¹, even under ambient conditions. Numerous reports pertaining to graphene-based electronic devices include transistors, sensors, photodetectors, and electromechanical resonators as targeted applications.

Several different methods have been developed for the synthesis of graphene including chemical vapor deposition and epitaxial growth on metal surfaces, exfoliation, controlled reduction of graphene oxide, epitaxial growth on insulating silicon carbide crystal, and microwave-assisted synthesis. Graphene oxide, made by controlled oxidation of graphite, is also widely used owing to its suitability for introducing heteroatoms and forming highly porous nanostructures.

Another class of important graphene derivatives are the so-called nanographenes or graphitic nanoparticles, which show promise in the areas of quantum electronics, photovoltaics, electrocatalysis, and bio-imaging. Extensive theoretical studies, mostly pertaining to graphene nanoribbons, have pointed to the correlations between the shape and size of nano-graphitic domains and their electronic structure. Both theoretical and experimental work point to the importance of electronic states localized along the zigzag edges. (Phys. Rev. B 1996, 54, 17954-17961). Nanostructured carbons from templated organic precursors have been prepared using organic polymers as precursors. A variety of templating strategies have been developed to obtain nanostructured carbons with different architectures such as mesoporous or nanoporous carbons, carbon nanocomposites (e.g., with magnetic particles), and discrete carbon nano-objects including nanotubes and hollow carbon nanoparticles.

### SUMMARY

The invention described in this specification generally relates to carbon-based nanomaterials comprising graphitic domains that are doped with heteroatoms. The invention includes such heteroatom-enriched partially-graphitic nano-carbon materials, processes for the production is such materials, methods of using such materials, and articles or devices comprising such materials.

In one example, a process for producing a carbon nanomaterial comprises forming a phase separated (co)polymer having a carbon precursor phase and a sacrificial phase. The sacrificial phase is chemically or thermally removed and the carbon precursor phase pyrolized to convert the carbon precursor phase into a carbon material. The carbon material comprises nanographene structures with edge-on topology to an outer surface of the carbon material or to a surface of a pore in the carbon material. The carbon material may optionally be ground into a powder.

In another example, a particulate carbon nanomaterial comprises nanographene structures with edge-on topology to an outer surface of the carbon material particles or to a surface of a pore in the carbon material, wherein the nanographene structures comprise heteroatoms located along the edges of the graphene sheets.

It is understood that the invention described in this specification is not necessarily limited to the examples summarized in this Summary.

### BRIEF DESCRIPTION OF THE DRAWINGS

Various features and characteristics of the invention described in this specification may be better understood by reference to the accompanying figures, in which:

FIG. 1 is a schematic diagram illustrating a procedure used to form ordered carbon structures comprising π-π stacking of lamellae morphologies as seen by GIWAXS;

FIGS. 2A-2E are graphs showing N₂ sorption characterization for CTNCs prepared at various pyrolysis conditions: (a) isotherm curves, (b) their corresponding PSDs in which the pyrolysis time was fixed as 0.5 h, (c) isotherm curves, (d) their corresponding PSDs in which the pyrolysis temperature was fixed as 700° C., and (e) mechanism of thermal chemistry of PAN carbonization and XPS for CTNC;

FIGS. 3A-3C are graphs showing elemental analysis results for CTNCs pyrolyzed at different temperatures: (a) a survey scan plot, (b) atomic ratio changes obtained by XPS, and (c) atomic ratio changes obtained by combustion method;

FIGS. 4A and 4B are graphs showing capacitance values with various nitrogen contents in CTNCs: (a) plot of C_{g} and (b) Cₛₐ as a function of N/C atomic ratio;

FIGS. 5A-5C illustrate the characterization of supercapacitors built with CTNC electrodes, wherein (a) is a schematic diagram of a proposed mechanism of pseudocapacitance, (b) is a graph comparing supercapacitor performance in acidic and basic electrolytes, and (c) is a graph showing a correlation between geometric capacitance and nitrogen content with an inset schematic diagram;

FIG. 6 is a graph showing XRD profiles for CTNC, wherein the (002) diffraction peak is centered at a 2θ˜25°, which corresponds to π-stacking of nanographitic platelets, and the width of the (100) peak is centered at a 2θ˜44°, which can be used to assess lateral size Lₐ;

FIGS. 7A-7E are graphs showing XPS high resolution N is spectra, and FIG. 7F is a graph showing the change of nitrogen functional groups in CTNCs pyrolyzed at various temperatures;

FIGS. 8A and 8B are graphs showing (a) cyclic voltammetry curves for oxygen reduction reaction experiments using nanoporous carbon from an AN₉₉-b-BA₇₀ precursor at scan rates of 10 mV/s in N₂ saturated and O₂ saturated 0.1 M KOH aqueous solution (Reference electrode: SCE) and (b) cyclic voltammetry curves for nanoporous carbon formed using a silica template and PAN/ZnCl₂ solution as carbon precursor in O₂-saturated and Ar-saturated 0.1 M KOH solutions;

FIG. 9 is a schematic diagram illustrating the effects of modifying the relative electronegativity of zigzag, α_{z}, and armchair, αₐ, edges of a graphene sheet; FIGS. 10A and 10B are graphs showing cyclic voltammetry curves for ORR catalyzed by nitrogen-enriched nanocarbon, with scanning rates of: (a) 10 mV/s and (b) 100 mV/s, and in a solution of 0.1 M KOH (aq.);

FIGS. 11A and 11B are graphs showing Rotating Disc Electrode (RDE) linear sweep voltammograms (LSV) of [CoN₄]₃/C supported on a GC electrode in 0.1 M KOH saturated with O₂ at different rotation rates, wherein (a) shows the original LSV results, and (b) shows a Koutechy-Levich plot of J⁻¹ vs w^{-1/2} at different electrode potentials (the symbols are experimental data obtained from (a) and the lines are linear regressions;

FIGS. 12A and 12B are bar graphs showing the results of photocatalytic water reduction with ball milled (BM)-CTNC₇₀₀, wherein all of the experiments used 4 mg of WRC and 0.1 mM PS, with MeCN/H₂O/TEA as specified, unless stated otherwise, and wherein (A) shows H₂ production from initial observed activity, control studies and a comparable Pt system, and (B) shows catalytic performance with various sample processing/preparation conditions;

FIG. 13 is a diagram showing SEM images of BM-CTNC (left), corresponding morphology (bottom inset), and nanoparticles formed (right inset), with an AFM image of BCP precursor (top inset) and a DLS of filtered BM-CTNC (right);

FIGS. 14A and 14B are graphs showing electrochemical activity of CTNCs prepared under different pyrolysis temperatures, wherein (a) shows linear sweep voltammograms (20 mV/s) recorded in 0.5 M H2SO4 with a graphite counter electrode after 1000 initial CV scans between 0 and −0.8 V vs SCE (at 100 mV/s), and (b) shows linear sweep voltammograms (20 mV/s) recorded in 0.5 M H2SO4 with a Pt mesh counter electrode after 1000 initial CV scans between 0 and −0.8 V vs SCE (at 100 mV/s);

FIGS. 15A and 15B are graphs showing (a) operating overpotentials as a function of pyrolysis temperature corresponding to the polarization curves shown in FIG. 14A, and (b) operating overpotentials as a function of pyrolysis temperature, wherein the numbers above the bars indicate amount of Pt in the vicinity of the surface measured by XPS;

FIGS. 16A and 16B are graphs showing (a) “activation” of the CTNC-800 electrode upon potential cycling with Pt CE between 0 and -0.8 V vs. SCE in 0.5 M H2SO4, wherein the dashed line denotes activity obtained after short cycling between −0.8 and +1 V vs SCE, and (b) Tafel plots for the corresponding cycle number and their slopes;

FIG. 17 shows pristine SEM images of CTNC-600 pt (top left), 700 pt (top right), 800 pt (bottom left) and 900 pt (bottom right);

FIGS. 18A-18D are graphs showing adsorption of U(VI) by PANCs and CTNCs;

FIG. 19 is a schematic diagram illustrating the chemistry of thermal carbonization of PAN, including thermal stabilization (left) and pyrolysis (right) which involves dehydrogenation and denitrogenation eventually leading to partially graphitic structures;

FIG. 20 is a schematic diagram illustrating pyrolysis involving a dehydrogenation, loss of pyridinic, pyrrolic, and pyridonic nitrogen atoms, and the formation of quaternary nitrogen atoms;

FIG. 21 is a schematic diagram illustrating the mechanism of CO₂ reduction when electrocatalyzed by edge-pyrindine functionalized graphene;

FIG. 22 is a schematic diagram illustrating various polymeric heteroatom precursors for the production of functional carbonaceous materials; and

FIG. 23 is a schematic diagram illustrating a process for producing nanoporous carbon in which (a) a colloidal silica aqueous suspension is provided, (b) the colloidal silica suspension is treated in the presence of PAN/ZnCl₂ in aqueous solution, (c) the freeze drying of the resulting PAN/silica composite material and subsequent carbonization, and (d) the silica etching by HF solution, thereby forming the nanoporous carbon.

The reader will appreciate the foregoing features and characteristics, as well as others, upon considering the following detailed description of the invention according to this specification.

### DESCRIPTION

The following abbreviations may be used in this specification, including the drawings and/or the claims.
Physical vapor deposition (PVD)
Chemical vapor deposition (CVD)
Controlled radical polymerization (CRP)
Atom transfer radical polymerization (ATRP)
Nitroxide mediated polymerization (NMP)
Reversible addition fragmentation transfer (RAFT)
Acrylonitrile (AN)
n-Butyl acrylate (BA)
Methyl 2-bromopropionate (MBP)
2-Bromopropionitrile (BPN)
N,N,N′,N″,N″-pentamethyldiethylenetriamine (PMDETA)
2,2′-bipyridyl (bpy)
Dimethylformamide (DMF)
Dimethylsulfoxide (DMSO)
Tetrahydrofuran (THF)
N-methyl-2-pyrrolidone (NMP)
Poly(butyl acrylate) (PBA)
Polyacrylonitrile (PAN)
Polymethylmethacrylate (PMMA)
Poly(lactic acid) (PLA)
Poly(ethylene oxide) (PEO)
3-(Trimethoxysilyl)propyl methacrylate (TMSPMA)
Copolymer-Templated Nitrogen-enriched porous nanocarbons (CTNC)
Grazing incidence wide angle x-ray scattering (GIWAXS)
Differential scanning calorimetry (DSC)
Small/wide angle X-ray scattering (SAXS/WASX)
Oxygen reduction reaction (ORR)
Atomic force microscopy (AFM)
X Ray Diffraction (XRD)
X-ray photoelectron spectroscopy (XPS)
Discrete Fourier Transform (DFT)
Gas chromatography-mass spectrometry (GC-MS)
Surface area normalized capacitance (Cₛₐ)
Mass normalized capacitance (C_{g})
Pore size distributions (PSD)
Barett-Joyner-Halenda (BJH)
Micropore surface area (S_{mic})
Mesopore surface area (Sₘₑₛ)
Surface area (S_{BET})
Zigzag edge (α_{z})
Armchair edges (αₐ)
Highest Occupied Molecular Orbital (HOMO)
Parriser-Parr-Pople (PPP)
Zerner's Intermediate Neglect of Differential Overlap (ZINDO)
Freeze-pump-thaw (FPT)
Thermogravimetric analysis (TGA)
Transmission electron microscopy (TEM)
Cyclic voltammetry (CV)
Linear Sweeping Voltammograms (LSV)
Galvanostatic charge-discharge (CD)
Electrochemical impedance spectroscopy (EIS)
Atomic Force Microscopy (AFM)
Glassy carbon (GC)
Saturated calomel electrode (SCE)
Rotating disc electrode (RDE)
Ball Milled (BM)
Binding Energies (BE)
Basal Quaternary Nitrogen Species (N-Q)
Full Width at the Half Maximum (FWHM)
Order-Disorder Transition (ODT)

As described above, the present invention relates to carbon-based nanomaterials comprising graphitic domains that are doped with heteroatoms. This new class of functional carbons is characterized by tunable morphology that can be engineered by controlling the composition and microstructure of precursor copolymers. The nanocarbon materials described in this specification can comprise nanoporous carbon materials with highly accessible heteroatoms located on the edges of nano-graphitic domains exposed on the accessible surfaces of the carbon structures. The heteroatom-doped nano-graphene structures can be formed as a result of controlled stabilization, crosslinking, and pyrolyzing of a phase separated supramolecular template comprising a carbon precursor in one phase under controlled environmental conditions. The resulting functional carbons find utility in multiple applications. The selection of conditions for the preparation of structured carbonaceous materials with highly accessible heteroatoms of differing pre-determinable compositions located on the surfaces of the carbons enhances the performance of the formed carbons in such applications

Heteroatom-enriched nanocarbons can be prepared from biphasic macromolecular precursors. Different polymers and co-polymers are commonly immiscible at a molecular level, due to entropic reasons, and when two different polymers are blended together they phase separate macroscopically, often with phase domain sizes much greater than 1 micron. However, when two different blocks of well-defined polymers are covalently attached, as in block or graft copolymers, the phase separation is confined to the nanoscale, typically from about 5 nanometer to about 100 nanometers. The nanoscale morphology in block and graft copolymers is dictated by the attempt to minimize the interfacial area between the phases while avoiding stretched chain conformations, which are prohibitively low in entropy. The three most typical morphologies observed for binary systems are spheres, cylinders and lamellae. (Physical Properties of Polymers Handbook, 1996, 427-433).

The synthesis of well-defined block copolymer precursors comprising functional polar comonomers required for the approach described above can be made possible through the use of controlled radical polymerizations. Radical polymerization is a chain growth process in which the growing chain end is a free radical. Addition of subsequent repeat units to the chain involves homolytic bond cleavage within incoming monomers. Since this type of bond cleavage can be achieved in the widest group of monomers, in contrast to ionic polymerizations, which require monomers containing electron withdrawing or donating groups, radical polymerization is the most widely applicable chain growth technique. However, free radical polymerization suffers from a critical drawback: free radicals have a high tendency to undergo chain termination through combination, disproportionation, and chain transfer. This makes free radical polymerization practically useless if one is aiming to synthesize polymers with predictable composition, topology, controlled architecture, and predetermined site specific functionalities.

The limitations of free radical polymerization have been overcome through the introduction of reversible-deactivation radical polymerization (RDRP) procedures (Pure Appl. Chem. 2010, 82, 483-491), also known as controlled radical polymerization (CRP) procedures, and including atom transfer radical polymerization (ATRP) procedures. (Chem. Rev. 2001, 101, 2921-2990; Chem. Rev. 2007, 107, 2270-2299.]. Such procedures may also include nitroxide mediated polymerization (NMP) (Chemical Reviews 2001, 101, 3661-3688) and reversible addition fragmentation transfer (RAFT) polymerization (Aust. J. Chem. 2009, 62, 1402-1472). These RDRP procedures opened the way to “macromolecular engineering” of various novel materials, including polymers with controlled topologies (stars, combs, hyperbranched, controlled networks), compositions (block, grafts, gradient copolymers) and pre-determinable site selected functionalities (side and end functionalities, macromonomers, multifunctional copolymers) and various classes of hybrid materials. Early work on the use of RDRP procedures to produce nanocarbon precursors is described, for example, in U.S. Patent Application Publication No. 2003/0185741 A1, which is incorporated by reference into this specification.

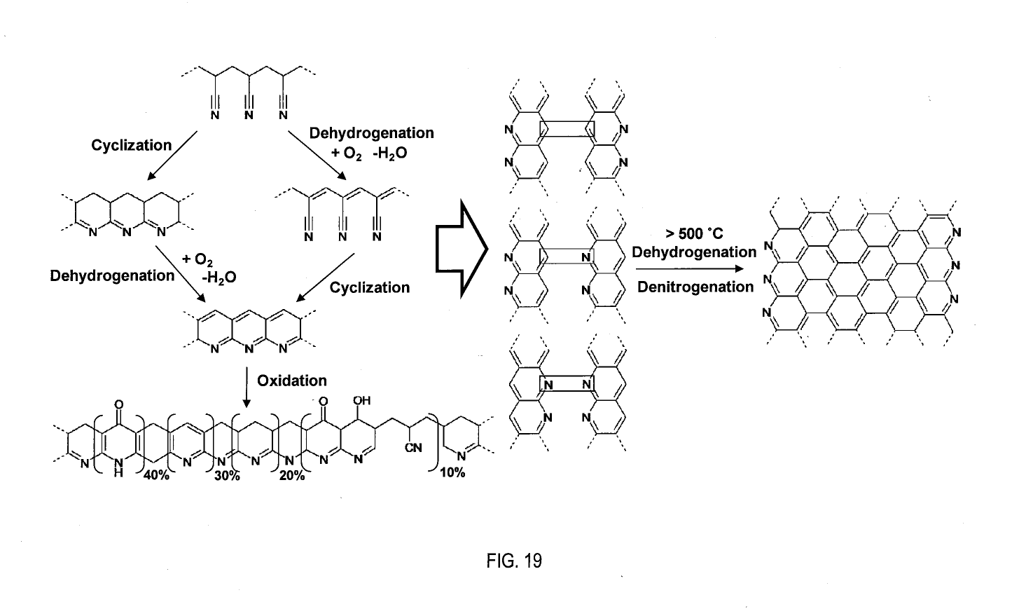

In various examples, heteroatom-enriched partially-graphitic nano-carbon materials can be produced from precursors (co)polymers, such as poly(acrylonitrile), for example, (see FIG. 19), synthesized using RDRP procedures. The precursor (co)polymers are subjected to controlled pyrolysis to provide carbons with retained morphology. The robustness of this approach has been demonstrated for a range of carbon precursor/sacrificial block/material configurations, as described in International Publication No. WO 2002/081372 and J. Am. Chem. Soc. 2002, 124, 10632-10633, which are incorporated by reference into this specification. After their nanostructure is fixed through chemical crosslinking (ACS Nano 2012, 6, 6208-6214) or thermal crosslinking (Chem. Mater. 2011, 23, 2024-2026), these materials are converted into porous nanocarbons with the morphology of the formed carbon structures closely resembling the morphology of the precursor PAN or other polymer segment(s) present in the starting material. Prior examples indicated that pyrolysis of a phase separated block copolymer with a gyrodal morphology resulted in formation of a porous carbon structure wherein the porous material is composed of a fraction of nanographene “clusters” containing stacked graphene sheets (WO/2011/022050).

As described in this specification, the nitrogen functionalities originating from PAN segments can play a crucial role in various applications. The combination of versatile processability of macromolecular precursors and efficient incorporation of heteroatoms at edge locations providing accessibility at the walls of the former phase separated (co)polymer provides an effective route for synthesizing the next generation of functional nanocarbon materials.

Earlier work on PAN carbonization by the present inventors (see FIG. 19) focused primarily on the preservation of nanoscale morphology and on the benefits stemming from the presence of nitrogen heteroatoms originating from the polyacrylonitrile precursor present in a gyrodal phase separated copolymer. This work included the demonstration that when these copolymer-templated nitrogen-enriched porous nanocarbons (CTNC) were used as electrodes in supercapacitors, they yielded capacitances per unit surface area, i.e. geometric capacitance, several times higher than conventional porous carbons, over 30 μF/cm² vs. ˜10 g/cm². Furthermore, it was indicated that CTNCs could act as metal-free ORR catalysts or as CO₂ sorbent materials. See WO 2011/022050; J. Am. Chem. Soc. 2005, 127, 6918-6919; J. Am. Chem. Soc. 2012, 134, 14846-14857 (supercapacitors); Macromol. Chem. Phys. 2012, 213, 1078-1090 (enhanced electrochemical performance); Chem. Commun. 2012, 48, 11516-11518 (CO₂ sorbents).

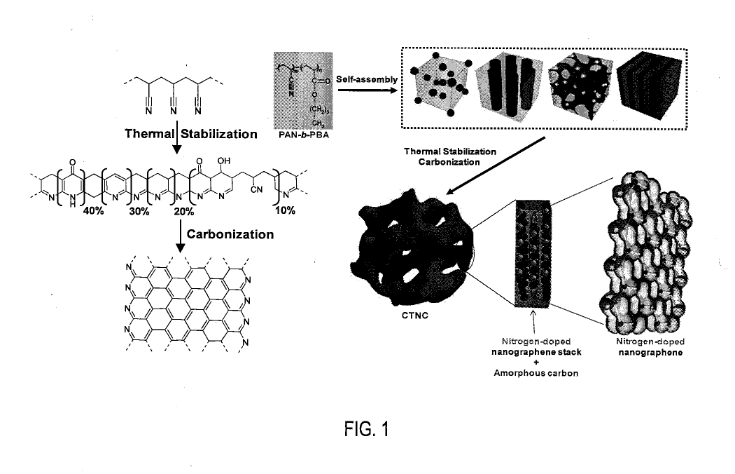

Subsequently the inventors hypothesized that all these effects pointed to a synergy between the nanographitic edge heteroatoms, primarily pyridinic nitrogens, and nonbonding zigzag edge electrons. Furthermore, the high availability of pyridinic nitrogens indicated that nanographitic domains within carbon framework are oriented with their nitrogen-rich zigzag edges facing the pore walls, and that such orientation is facilitated by the molecular orientation of the self-assembled macromolecular precursors, as shown in FIG. 1. Without intending to be limited by the explanation, it is believed that the formation of a nanographene stack is based on prior formation of crystalline areas in the first formed polyacrylonitrile phase and that the dimensions of the formed nanographene stack would be influenced by the molecular weight of the PAN segment and the self-induced or stress-induced crystallinity in the PAN domain. The nitrogen functionalities or other heteroatoms originating from, or added to, the phase separated segmented copolymer can play a crucial role in various applications.

Notwithstanding that the porous CTNC nanocarbons are the exemplary carbons that are primarily discussed in this specification, carbons formed from phase separated block copolymers with other morphologies would also express the same accessible nanographene structures with accessible nitrogens. These discrete carbons structures would exhibit the same, similar, or even enhanced activity in the catalytic processes discussed below if the individual carbon structures were formed on a solid substrate such as an electrode or incorporated as a part of a catalyst system.

In one example of the invention, the combination of versatile processability of the macromolecular precursors combined with controlled crosslinking of the precursor material under different atmospheres and pyrolysis at different temperatures, also under controlled atmospheres, provide efficient retention of heteroatoms combined with their accessibility at pore walls or on the surface of the individual formed carbon structures. The controlled pyrolysis procedure provides site selective heteroatoms on the edges of nanographitic domains which, in combination with the non-bonding character of π-electrons on zigzag edges of stacked nanographitic sheets, endow these materials with the ability to effectively participate in a wide range of applications that rely on charge transfer and/or formation of coordination bonds. The disclosed materials are at the core of the disclosed strategy for synthesizing the next generation of functional nanocarbon materials targeting specific charge transfer reactions and reactions involving formation of coordination bonds.

In a surprising development it was discovered that if the functional nanocarbon structured materials were subjected to grinding or ball milling a fraction of well-defined carbon nanoparticles were formed that displayed superior catalytic properties in several applications. Without wishing to be limited by the explanation, it is believed that these robust functional nanocarbon materials could result from the exposure of a greater fraction of the nanographitic domains arising from carbonization of the organized crystalline domains present in the first formed segmented copolymer or induced during the annealing/stabilization procedure or from exfoliation of the staked domains to expose sheets of the edge functionalized nanographitic domains.

The present disclosure provides procedures for the optimal synthesis, and use of the formed functional novel porous carbon materials and nanostructured carbons having heteroatoms on the edges of nanographene sheets, preferably stacked nanographene sheets that can be specifically tailored for use as electrocatalysts for oxygen or carbon dioxide reduction; photocatalysts for water reduction, electrodes for hydrogen evolution reaction, substrates for metal sequestration, or metal catalyst supports for heterogenous catalysis in addition to providing improved materials for supercapacitors, lithium batteries, fuel cells or cathodes for dye-sensitized solar cells.

One embodiment of the invention includes the development of synthetic and processing routes to a new class of porous CTNCs, which combine high surface area with well-defined nanostructure and presence of electrochemically available nitrogen and/or other heteroatoms at the accessible surfaces of the materials. When targeting heterogeneous catalysis the incorporated heteroatom can act as a stabilizer to hold the metal to the surface of the carbon or can act as a ligand which provides additional activity. In a further development of the invention it was discovered that grinding or ball milling (BM) the first formed porous CTNCs the formed carbon powders contained a fraction of uniform sized nanocarbon particles that displayed improved performance in targeted catalytic procedures. An alternative approach to BM is the direct formation of nano-sized carbons by pyrolysis of phase separated PAN block copolymers with a minority phase of PAN.

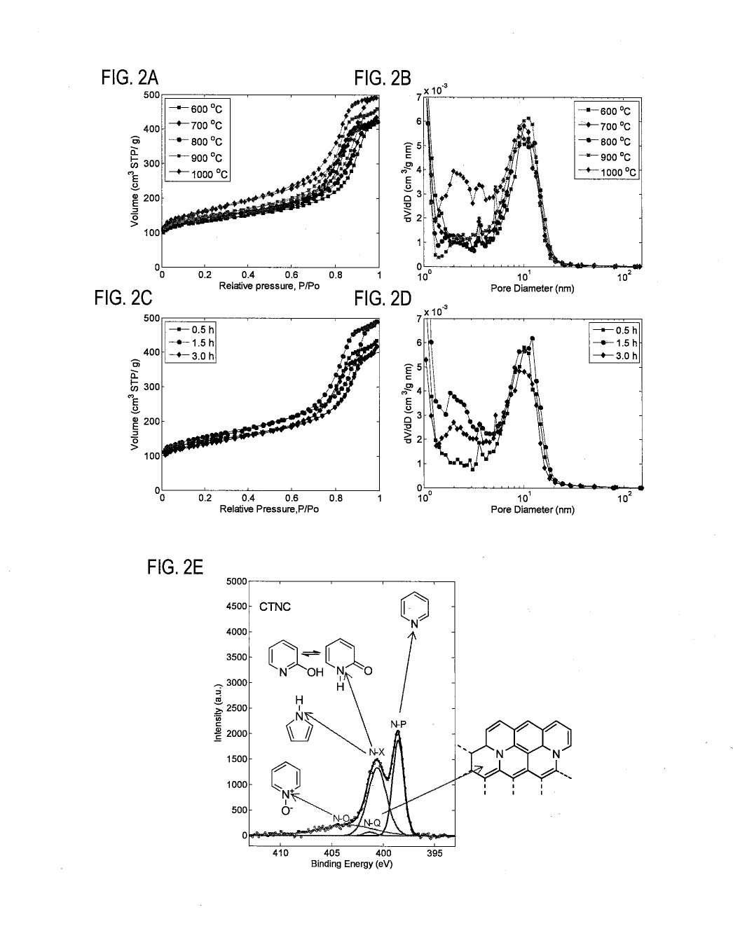

The thermal treatment process used in this work is superficially similar to the procedure used in the formation of carbon fibers. In a non-limiting example first stage involves heating an exemplary poly(butyl acrylate)-b-poly(acrylonitrile) block copolymer (PBA-b-PAN) with a composition that phase separated into a gyroidal morphology in the presence of an oxidizing atmosphere at temperatures between 200° C. and 300° C., which results in partial dehydrogenation and some cyclization of PAN prior to switching to an inert atmosphere and continued heating to higher temperatures to pyrolyze the sacrificial PBA phase and carbonize the PAN phase (see FIG. 1). Following the disclosed stabilization and pyrolysis procedures the characteristic surface morphologies of the phase separated block copolymer precursors are still discernable in AFM images after thermally controlled pyrolysis. Nitrogen adsorption measurements revealed that upon removal of the sacrificial block of the templating material the formed carbon based materials became nanoporous (see FIGS. 2A-2E) with the predominant pores the same size as the domains of the sacrificial polymer. The high fidelity of the preservation of the nanostructure upon conversion from copolymer to carbon was particularly evident in ultra-thin films with long-range ordered lamellar structures, as shown in FIG. 2 in WO/2011/022050.

As indicated in the upper schematic of FIG. 1, one can preselect the size and morphology of the PAN domains in the first formed segmented copolymer by forming copolymers with different mole ratios of the PAN and sacrificial polymer and molecular weight (MW) of each segment to generate carbons with different shapes. Concurrently, as one prepares block copolymers with the same ratio of monomers but different degrees of polymerization (DPs) one would obtain carbon structures with the same shape but with different predeterminable sizes. It is currently expected that all of the different morphologies of the formed carbons would result in formation of nano-graphitic domains with edge functionalities accessible on the surface of the carbon structures.

Surprisingly, the inventors have discovered that the conditions employed during the stabilization and carbonization procedures modify the number, position, and chemical structure of the heteroatoms in the formed edge on nanographitic sheets (see FIGS. 2E, 3A-5C, and 20) and thereby provide carbon based functional materials with tunable properties suitable for several “green” (i.e. metal free) catalytic transformation reactions.

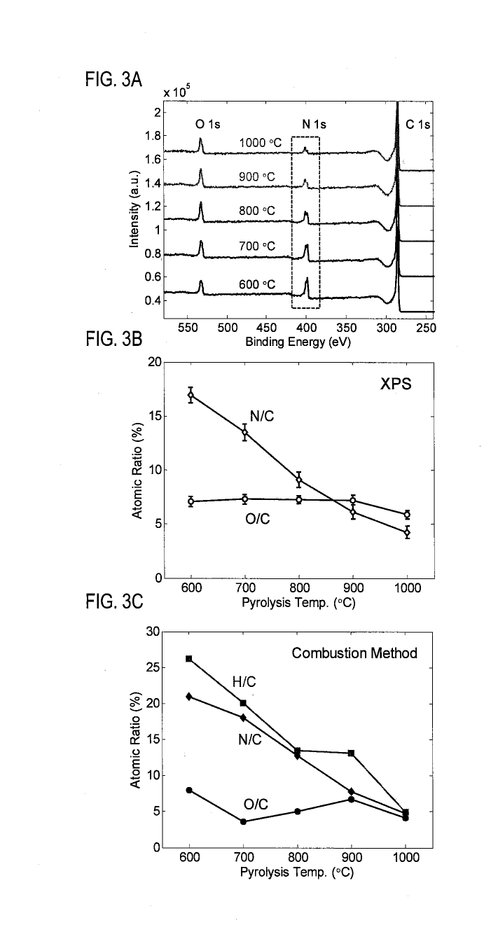

The nanoporous carbons are unique in that heteroatoms, such as nitrogen, phosphorus, and sulfur are, or can be, located on the edges of nano-graphitic domains exposed on pore walls, or surfaces of formed carbons, as a result of the pre-organized supramolecular template and the conditions employed during carbonization (see FIGS. 3A-3C). What distinguishes the disclosed approach, on the mechanistic level, is the explicit recognition of the synergies emerging from the combination of the edge location of heteroatoms and edge-availability of non-bonding π-electrons in pre-organized nano-graphitic structures and the unexpected results from conducting the pyrolysis reaction under different specific conditions, for example, between 500° C. and 1000° C., preferrably between 600° C. and 800° C., optionally in the presence of different atmospheres, to prepare carbonaceous materials with differing composition and differing reactivity in selected and targeted chemical transformations. Potential atmospheres for pyrolysis can include inert atmospheres such as argon, activating atmospheres such as N₂ or CO₂, mixed atmospheres such as O₂/N₂ or O₂/CO₂, steam, chlorine-containing, or ammonia-containing atmospheres. All influence the structure and composition of the formed carbon and hence performance as catalysts.

It had been confirmed that the “clean” exposure of edge heteroatom functionalities can be achieved through macromolecular templating based on the carbonization of segmented copolymers, or hybrid materials comprising the heteroatom rich carbon source and an immiscible sacrificial block. In this example (see FIG. 1), the precursor copolymers organize through self- or directed-assembly into well-defined nanoscale morphologies, which after being fixed through thermal or chemical cross-linking of the carbon precursor phase are converted into partially graphitic nanocarbons with the final morphology resembling that of the starting material.

In the non-limiting example described in greatest detail in this specification, the use of a copolymer providing a bi-continuous phase separated morphology, the desired nanoscale porosity, and thus high surface area, of the system is achieved through the thermal decomposition of the sacrificial block. Other phase separated precursor morphologies would provide functional nanostructured carbons with different shape and size, and the activity of the formed carbons in targeted applications would be similar. Indeed it is now possible to capitalize on these insights to develop a wider range of copolymer templated heteroatom enriched nanocarbons targeting a much broader range of applications in addition to exemplifying and improving the performance of the formed nanostructured carbons in prior envisioned applications.

An additional benefit of the macromolecular templating approach is that it affords the benefits of a wide spectrum of industrial scale fabrication processes, which, in turn, opens the way to targeting diverse macroscopic forms, such as free standing thin films, coatings, fibers, carbon based monoliths, and nano/micro particles that additionally can influence the nano-structure of formed functional carbons. A review article providing the state of the art for preparation of porous polymers by templating coauthored by one of the inventors—(Chem. Rev., 2012, 112 (7), 3959-4015)—is incorporated by reference to provide information on procedures for incorporation of macropores, and to modify the overall surface area of the carbons while retaining access to functional nano-graphitic sites. To exemplify incorporation of macropores into a carbon precursor block copolymer, procedures utilizing a high internal phase emulsion (HIPE) process are described below.

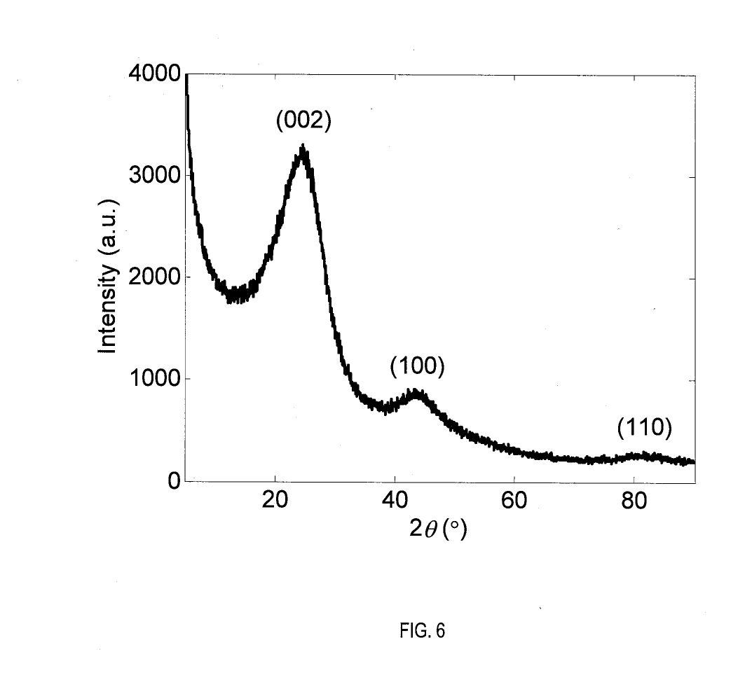

The X-ray diffraction (XRD) pattern of such prepared CTNC revealed the presence of broad Bragg peaks indicative of the presence of nanographitic structures commonly observed in pyrolytic carbons (see FIG. 6). A crude estimate of the lateral size of partially graphitic domains based on the width of the (100) peak indicated that they did not exceed 2-3 nm. Likewise, based on the width of the (002) peak, nano-graphitic domains were comprised of no more than 2-3 π-stacked nanographene sheets. However as exemplified below the lateral size of partially graphitic domains are dependent on the MW of the PAN segments and hence could be adjusted in a systematic manner.

### Effect of Pyrolysis Conditions on the Structure of Formed Nanocarbons and Effect on Performance as Supercapacitors.

According to the mechanism of PAN carbonization, de-nitrogenation and dehydrogenation increase with increasing pyrolysis temperature. Thus, if the nitrogen atom is the primary cause for the extraordinarily high surface area normalized capacitance (Cₛₐ) of copolymer template porous nanocarbons (CTNC) via the pseudocapacitance effect, it can be expected that the decrease in nitrogen content resulting from increasing pyrolysis temperature would reduce Cₛₐ as well as mass normalized capacitance (C_{g}) and additionally influence the porous structure of CTNCs which should affect the supercapacitor performance. Therefore supercapacitor performance could be dependent on the carbonization conditions such as a pyrolysis temperature, time and contacting atmosphere.

Based on the above hypothesis, a series of CTNCs was prepared under different pyrolysis conditions, initially by varying pyrolysis temperatures from 600° C. to 1000° C. while keeping the pyrolysis time constant at 0.5 h and then preparation of two further CTNC samples with pyrolysis times of 1.5 h and 3.0 h at 700° C. to study the effect of pyrolysis time. Their nitrogen sorption and the corresponding pore size distributions (PSD) curves on the formed CTNCs, which were calculated from the desorption branch of the isotherms using the Barett-Joyner-Halenda (BJH) method, are shown in FIGS. 2A-2E. All CTNCs exhibited the hysteresis loops at relative pressure of 0.6-0.9 in isotherm curves (FIGS. 2A and 2C show the temperature dependent pyrolysis CTNC's and time dependent pyrolysis CTNC's respectively), which can be ascribed to the filling and emptying of the mesopores by capillary condensation/evaporation. The maximum PSDs are positioned at ˜10 nm of pore diameter, (see FIGS. 2B and 2D), regardless of their pyrolysis conditions.

The CTNC pyrolyzed at 1000° C. showed noticeably a higher distribution of pores between 1.5-6 nm diameters compared with others, which might be due to the collapse of micropores at high pyrolysis temperature. The increase of mesopores accompanying the decrease of micropores with increasing pyrolysis temperature was evidenced by the change of S_{mic}, and Sₘₑₛ values, provided in Table 1, which show that the CTNC formed by pyrolysis at 1000° C. provided maximum S_{BET} (564 m²/g) and Vₜₒₜ (0.76 cm³/g).

TABLE 1
Porosity and electrochemical data for the supercapacitors
built with CTNC's pyrolyzed under different conditions.

| | | pyrolysis temp.(° C.) | | | | | | |
|---|---|---|---|---|---|---|---|---|
| | | 600 | 700 | | | 800 | 900 | 1000 |
| | | pyrolysis time (h) | | | | | | |
| | | 0.5 | 0.5 | 1.5 | 3.0 | 0.5 | 0.5 | 0.5 |
| surface area | S_{BET} | 461 | 498 | 544 | 469 | 485 | 509 | 564 |
| (m²/g) | S_{mic} | 264 | 277 | 253 | 214 | 278 | 256 | 227 |
| | Sₘₑₛ | 210 | 223 | 311 | 247 | 220 | 254 | 328 |
| | Sₘₑₛ/S_{BET} | 0.46 | 0.45 | 0.57 | 0.53 | 0.45 | 0.50 | 0.58 |
| Pore volume | Vₜₒₜ (cm³/g) | 0.65 | 0.67 | 0.75 | 0.64 | 0.65 | 0.71 | 0.76 |
| 1M H₂SO₄ | C_{g} (F/g) ^{a} | 139 (5) | 166 (5) | 181 (11) | 151 (5) | 150 (6) | 110 (3) | 86 (4) |
| | Cₛₐ (μF/cm²) ^{b} | 30.2 | 33.3 | 33.2 | 32.2 | 30.9 | 21.7 | 15.3 |
| | Retention (%) ^{c} | 51.1 | 76.5 | 75.4 | 68.6 | 73.5 | 72.6 | 60.7 |
| 6M KOH | C_{g} (F/g) | 122 (7) | 125 (4) | 135 (12) | 114 (4) | 123 (6) | 105 (3) | 84 (5) |
| | Cₛₐ (μF/cm²) | 26.5 | 25.1 | 24.9 | 24.4 | 25.3 | 20.6 | 14.9 |
| | Retention (%) | 58.4 | 68.0 | 68.0 | 61.9 | 66.8 | 67.2 | 62.2 |
| 1M NaNO₃ | C_{g} (F/g) | 66 (3) | 74 (3) | 88 (5) | 76 (3) | 72 (3) | 78 (5) | 63 (3) |
| | Retention (%) | 25.8 | 52 | 37.9 | 31.2 | 28.7 | 38.4 | 41.3 |
| | Cₛₐ (μF/cm²) | 14.2 | 14.9 | 16.2 | 16.1 | 14.8 | 15.4 | 11.1 |
| | Retention (%) | 25.8 | 52 | 37.9 | 31.2 | 28.7 | 38.4 | 41.3 |

^{a} mass-normalized capacitance obtained at 0.1 A/g of current density using eq 1.
^{b} S_{BET}-normalized capacitance obtained at 0.1 A/g of current density.
^{c} Retention rate was determined by dividing a capacitance value obtained at 10 A/g by one obtained at 0.1 A/g.

A further increase in S_{BET} and Sₘₑₛ was also observed when the pyrolysis time increased from 0.5 h to 1.5 h at 700° C. of pyrolysis temperature, as shown in Table 2.

TABLE 2
XPS data for CTNCs pyrolyzed at various conditions.

| temp. | time | O/C | N/C | N—P | | N—X | | N—Q | | N—O | |
|---|---|---|---|---|---|---|---|---|---|---|---|
| (° C.) | (h) | (±0.5) | (±0.8) | BE | N—P/C | BE | N—X/C | BE | N—Q/C | BE | N—O/C |
| 600 | 0.5 | 7.1 | 16.9 | 398.6 | 6.7 | 400.5 | 7.0 | — | — | 403.3 | 3.2 |
| 700 | 0.5 | 7.3 | 13.5 | 398.5 | 4.8 | 400.6 | 5.8 | 401.3 | 0.2 | 403.5 | 2.7 |
| | 1.5 | 5.8 | 12.6 | 398.5 | 4.5 | 400.6 | 5.2 | 401.3 | 0.9 | 403.5 | 2.1 |
| | 3.0 | 6.8 | 10.9 | 398.5 | 3.6 | 400.6 | 4.6 | 401.3 | 1.0 | 403.5 | 1.7 |
| 800 | 0.5 | 7.3 | 9.1 | 398.5 | 2.6 | 400.6 | 4.3 | 401.3 | 0.7 | 403.2 | 1.6 |
| 900 | 0.5 | 7.2 | 6.1 | 398.5 | 1.4 | 400.6 | 2.3 | 401.3 | 1.1 | 403.3 | 1.4 |
| 1000 | 0.5 | 5.9 | 4.3 | 398.5 | 0.5 | 400.6 | 1.9 | 401.4 | 1.1 | 403.5 | 1.1 |

Their PSDs showed a considerable increase in pores having diameters between 1.5-5 nm (FIG. 2D), which was observed only at 1000° C. for CTNCs pyrolyzed for 0.5 h. However, the carbons formed after 3.0 h of pyrolysis time showed a drop in porosity over the whole range of pore diameter compared to the 1.5 h sample and the further decrease in micropores made its S_{BET} (469 m²/g) less than that of 0.5 h sample (498 m²/g). Overall, CTNCs prepared by various pyrolysis conditions exhibited 460-570 m²/g of S_{BET} values, while the mesoporosity (Sₘₑₛ/S_{BET}) with respect to the surface area was in the range of 0.4-0.6.

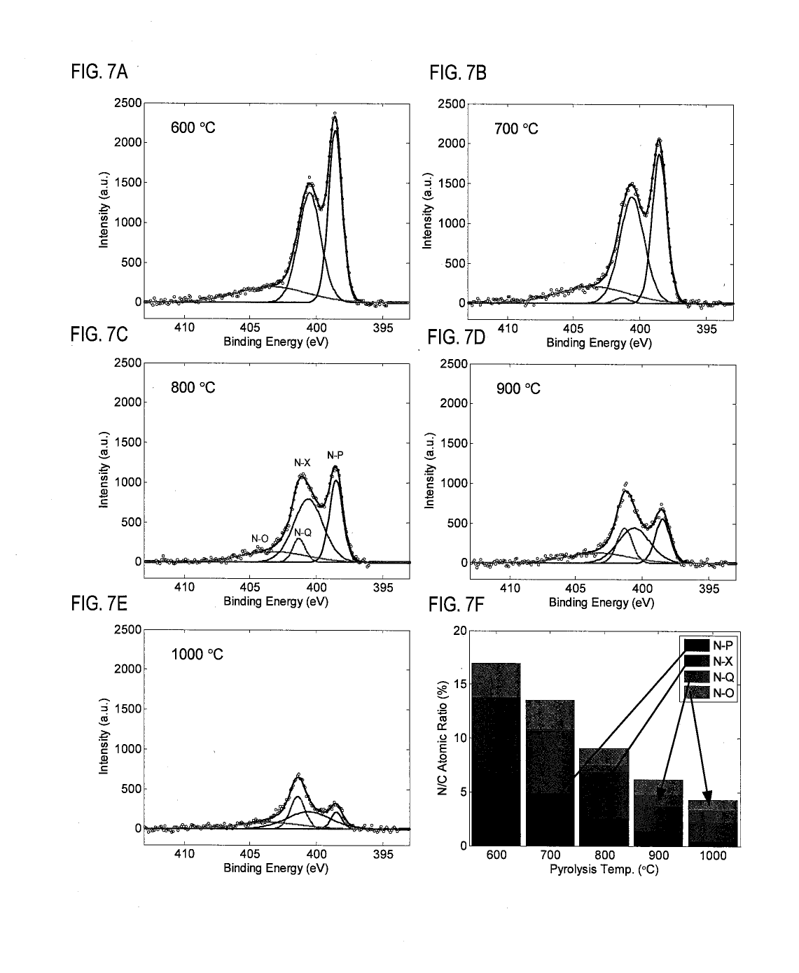

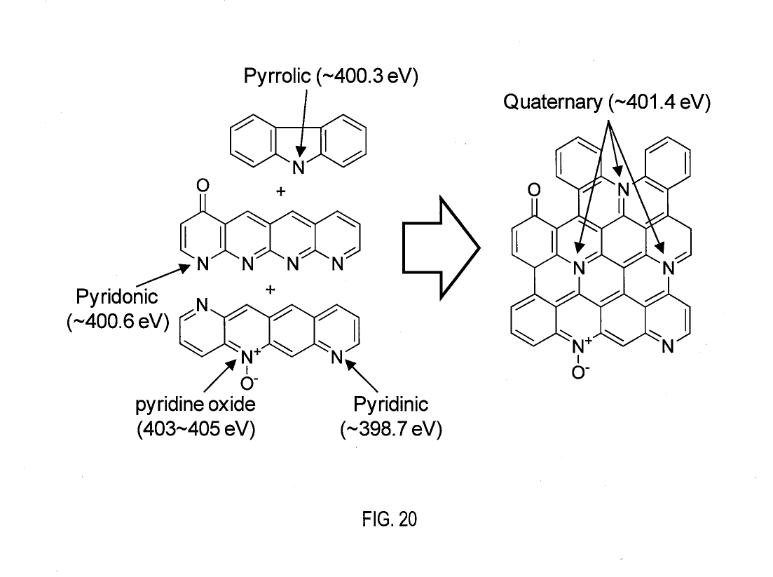

Table 2 lists the results of XPS analysis of the CTNCs pyrolyzed under different conditions illustrating that the number of nitrogen atoms in the final carbon decreased as pyrolysis temperature increased and also shows that the fraction of quaternary nitrogen atoms increased as pyrolysis temperature increased whereas all the other nitrogen functionalities decreased as shown in FIGS. 7A-7E. This change in nitrogen functionality with increasing pyrolysis temperature was also observed among the CTNCs prepared under different pyrolysis times while the pyrolysis temperature was fixed. The N-Q/C increased from 0.2% to 1.0% whereas N—P/C, N—X/C, and N—O/C decreased as the pyrolysis time increased from 0.5 h to 3 h (Table 2) at a pyrolysis temperature of 700° C. This can be explained by the proposed mechanism of PAN carbonization, which shows the formation of quaternary nitrogen atoms accompanied by the decrease in other nitrogen functional groups as shown in FIG. 20. It also shows some possible changes of nitrogen functionalities such as change from 5-membered pyrrolic nitrogen into the quaternary one, change from pyridinic nitrogen into the quaternary one, and loss of the pyridine/pyridone functionalities.

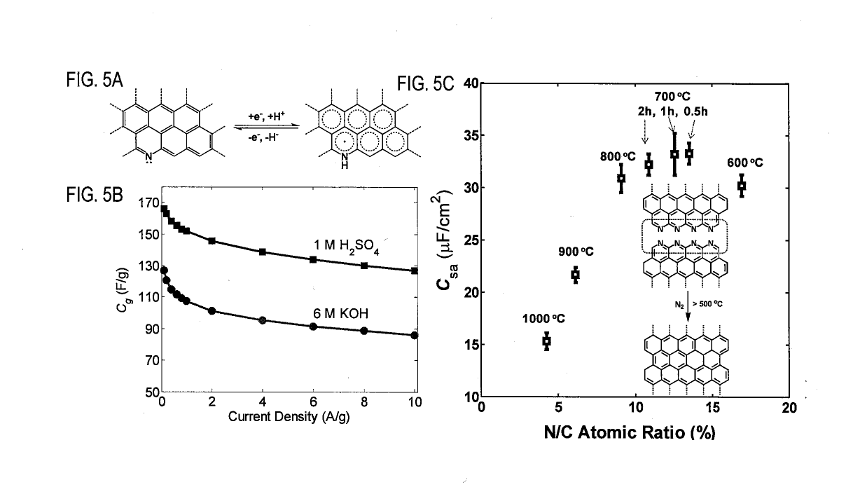

As noted in WO/2011/022050, nitrogen enriched porous nanocarbons could be employed as electrode materials for supercapacitors generating gravimetric capacitances approaching 200 F/g, which is comparable with conventional materials. This value was reached however with carbons possessing a much lower surface area (˜500 m²/g), translating to specific capacitances exceeding 30 μF/cm². In combination with the observation that enhanced specific capacitances were observed only in acidic electrolytes, the primary inventors proposed that this was evidence of faradaic processes facilitated by edge nitrogen heteroatoms exposed on pore walls (see FIG. 5A). As described herein, more detailed work revealed that this unusually high value was in direct correlation with the content of nitrogen heteroatoms originating from PAN precursor (see FIG. 5B). Various N/C atomic ratios can be achieved by altering the pyrolysis temperature due to the temperature facilitated de-nitrogenation process (see FIG. 5C inset). Therefore, the lower geometric capacitance observed from ˜18% N/C atomic ratio, carbonized at 600° C., compared to ˜15% N/C atomic ratio, carbonized at 700° C. was caused by high resistivity resulting from the smaller size of the graphitic regions obtained under such a low pyrolysis temperature.

### Physicochemical Characterization of CTNCs Obtained Under Various Pyrolysis Conditions.

A surface X-ray photoelectron spectroscopy (XPS) analysis was carried out on the CTNCs pyrolyzed at different temperatures in order to identify the nitrogen functional groups in CTNCs, which were considered to be the major cause of the pseudocapacitance effect, and the resulting scan plots are presented in FIG. 3A. The relative atomic compositions were obtained from the C 1s, N 1s, and O 1s peaks and FIG. 3B shows their changes with different pyrolysis temperatures. The nitrogen atomic ratio with respect to carbon atoms (N/C) in CTNC measured by XPS decreased with increasing pyrolysis temperature whereas there was no correlation between oxygen content (O/C) and the pyrolysis temperature. The elemental analysis by a combustion method (FIG. 3C) gave a similar result to that of XPS, indicating a comparable atomic composition between the accessible surface and the bulk carbon material. The decrease in both hydrogen and nitrogen content with increasing pyrolysis temperature can be explained by the mechanism of PAN carbonization, which involves de-hydrogenation and de-nitrogenation via a successive carbon ring fusion.

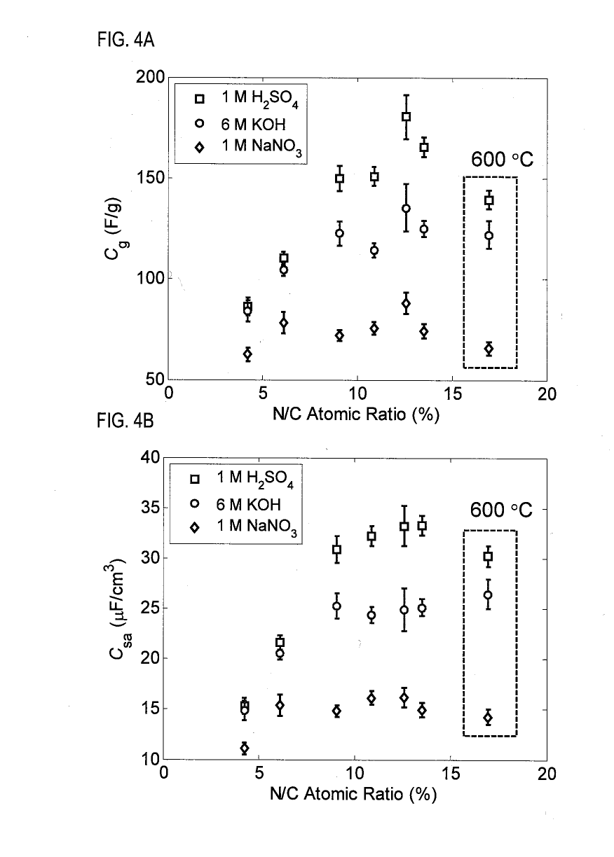

The direct relationships between the nitrogen content (N/C from XPS) and capacitance (C_{g} and Cₛₐ) are plotted in FIGS. 4A and 4B, respectively. The capacitance values measured in both acidic and basic electrolytes was proportional to the nitrogen content, except for the CTNC with ˜17% of N/C ratio, which was pyrolyzed at 600° C. The deviation of the CTNC pyrolyzed at 600° C. from the curve can be attributed to its high electrical resistance compared with other CTNCs. The high electrical resistance causes a high iR drop which appears immediately after changing the direction of applying current in the CD measurement resulting in a decrease in available capacitance.

As shown in FIG. 2E, the N 1s peak in the X-ray photoelectron spectrum (XPS) of one of the CTNC prepared for in this series of experiments, the sample pyrolized at 700° C., points to the presence of three major nitrogen species differentiated by their binding energies (BE). See FIG. 20: (i) pyridinic (N—P, BE≈398.5 eV), (ii) mixture of pyridonic (N—X, BE≈400.6 eV) and pyrrolic (BE≈400.3 eV), and (iii) pyridine oxide (N—O, BE≈403-405 eV) (Pels et al.; Carbon 1995, 33, 1641-53). The chemical environments of these nitrogen atoms revealed by XPS, 35% pyridinic, 43% pyridonic+pyrrolic, and 20% pyridine oxide, are consistent with their proposed location along the outer edges of accessible nano-graphitic domains. In addition to those “edge” nitrogens, the spectrum shown in FIG. 2E, also indicated the presence of a relatively small fraction (2%) of basal quaternary nitrogen species (N-Q, BE=401.4 eV).

The full width at the half maximum (FWHM) of the N—P peak observed in these analyses is almost one half of the width reported in literature by Pels for the pyridinic nitrogen in pyrolytic carbons derived from PAN, ˜1.3 eV vs. ˜2 eV, (Carbon 1995, 33, 1641-1653), thus highlighting the unusual degree of uniformity in the chemical environment of this species in the present materials, which is believed to be induced by the presence of the sacrificial phase in the first phase separated block copolymer. Such uniformity, preferentially providing a FWHM lower than 1.75 eV, can be viewed as another confirmation of preferential location of pyridinic nitrogen atoms on the exposed surfaces of pore walls, i.e. in the environment where they do not come into close contact with other neighbors. As discussed earlier, the pyridinic nitrogens, with the lone pair residing on the sp² orbital which is not a part of the aromatic system, can be expected to be the most electrochemically active species. The relatively high percentage of partially oxidized species (N—X, N—O) revealed by the XPS results shown, and discussed herein, implies that the oxidative stabilization conditions used in this initial study leads to an over-oxygenated structure. Accordingly, optimization of the yield of pyridinic nitrogen can be evaluated by exploring the effect of stabilization under milder conditions; lower temperatures, shorter reaction times, and lower partial pressure of O₂ in the contacting atmosphere, all of which would still assure sufficient crosslinking to provide the crucial preservation of the initial copolymer phase separated nanostructure.

Another important factor in the optimization of stabilization conditions is related to the goal of increasing the surface area of CTNCs, with the hope of significantly exceeding the performance of the discussed exemplifying nanostructured carbons in targeted applications e.g. to increase the supercapacitance of the carbon. One path to reach this goal with copolymer templating would be through the reduction of the lengths of PAN and PBA blocks. The main challenge associated with this approach is, however, the concomitant decrease of the order-disorder transition (ODT) temperature, which determines the thermal stability of copolymer nanostructure, thereby indicating extra care has to be taken to ensure sufficient crosslinking to preserve the first nano-phase separated structure prior to pyrolysis. Indeed, in the preliminary experiments with low degree of polymerization PAN-b-PBA the copolymer underwent an ODT well below 280° C.

One solution to this problem would be to appropriately decrease the stabilization temperature. The undesirable decrease of the efficiency of stabilization at lower temperatures could be compensated by extending the pyrolysis time, utilizing UV or gamma irradiation or use of strong base treatment as a potential replacement of air based stabilization as these procedures have been proved to be able to cross-link PAN at room temperature (J. Appl. Polym. Sci., 2013, 128, 2081-2088). Therefore milder de-hydrogenation or oxidation agents, such as I₂ and CO₂, should enhance crosslinking and hence stabilization of the PAN segments before pyrolysis. It has been demonstrated that the stabilization temperature of PAN can be suppressed in the presence of acidic moieties (Polym. Degrad. Stabil. 2008, 93, 1415-1421). Therefore, block copolymer precursors with small amounts of incorporated acid functionality in the PAN block should allow the preparation of copolymers with lower DP of the PAN segment that displays enhanced crosslinkability and enhanced surface area in the formed carbons. Another approach to increasing the surface area of the functional carbons would be to introduce a second sacrificial phase, e.g. silica particles or a second fugitive polymer phase such as PMMA, PLA, PEO, or the like.

These two approaches can be combined and an example is replacement of the PBA sacrificial block by 3-(trimethoxysilyl)propyl methacrylate (TMSPMA). The TMSPMA side chains can be cross-linked by aqueous/acid treatment yielding a thermally stable sacrificial component which will enhance the nanostructure preservation in the carbonization process. After carbonization, the cross-linked PTMSPMA matrix can be converted to SiO₂ which then be etched away by HF treatment. The in-situ formed SiO₂ will prevent the collapse of isolated carbon domain during carbonization.

A third counter intuitive approach would be to grind the first formed carbon structure to physically prepare smaller carbon structures.

### Controlling Carbonization Conditions.

It was determined that pyrolysis under CO₂ instead of N₂ can result in higher surface area, with CO₂ facilitating the generation of micropores through removal of amorphous carbon. However, such non-inert atmosphere can also decrease the content of nitrogen, especially if it is carried out at high temperature (>800° C.) (Chem. Commun. 2012, 48, 11516-11518). Therefore, in addition to using CO₂, carbonization under NH₃ atmosphere is also an option as it is expected to serve a dual purpose, acting as the activation gas and as a nitrogen-enricher. Another modification is carbonization in the presence of trace amounts of metal, e.g. Fe, Co, Ti, as it is expected that incorporated transition metal can act as a co-catalyst in certain applications, and it will be determined if the presence of residual of Fe or Co components in nitrogen-enriched nanocarbon can enhance the electrocatalytic activity for ORR. Indeed, as discussed later, the presence of platinum increases the activity of the CTNC in HER reactions.

In addition, conducting a post-carbonization hydrogenation process will be considered as an additional step to reduce the over-oxidized species while keeping in mind that too harsh a hydrogenation might cause passivation of the active heteroatom edge states.

### Dependence of Nanostructure Preservation on Copolymer Morphology.

As described above, in one embodiment of the invention, the preservation of nanoscale morphology upon carbonization of bulk biphasic materials allows the copolymer precursor to assemble into a stable three-dimensional bicontinuous framework. The morphology of the phase-separated block copolymers can be tuned by manipulating the chain lengths and volume fractions of the (co)polymer segments to achieve the formation of structures such as spheres, cylinders, gyroids, and lamellae. As shown schematically in FIG. 1, the best preservation of nanoscale morphology in these studies of stable free standing CTNCs has been achieved in materials derived from copolymer with bicontinuous morphology, yielding CTNCs with the highest surface area (see FIG. 1, lower central structure). As demonstrated herein this can be accomplished through the choice of the copolymer with PAN content high enough to lead to the formation of continuous carbon framework, not susceptible to collapse upon pyrolysis.

However, to fully elucidate the impact of the initial morphology on the preservation of the nanostructure, it was necessary to study the complete phase diagram of PAN-b-PBA system, by synthesizing and carbonizing materials over the broadest range of molecular weights and compositions. The initial focus was on copolymers in which PAN was a minority component as this can produce free standing nanostructured carbons with functional surfaces. If the precursor phase separated copolymer was deposited on a solid substrate and annealed prior to stabilization and pyrolysis, the individual cylinders or lamella should remain attached to the substrate and be able to efficiently participate in any of the discussed gas phase reactions. Such materials would be also suitable precursors for ball milling to generate functional nanocarbons with even higher surface area and exposed edge functional graphitic sheets. One can also expect that good preservation of morphology upon carbonization could be also obtained using precursors with PAN as a major component, where PAN would be forming a continuous phase and these materials could also be milled to generate increased fractions of accessible functional surfaces.

In a specific non-limiting exemplification of the utility of the tunability of the pore structure of CTNCs was examined by manipulating the size, or DP, and ratio of PAN and PBA blocks in PBA-b-PAN block copolymers and determining the influence on supercapacitor performance. This disclosed tunability of morphology and functionality is a unique advantage of nanocarbons formed from phase separated PAN copolymers for several potential applications. The nanoscale morphology caused by the phase separation between the blocks depends on the block length and composition and architecture of the segmented copolymers. Table 4 shows the composition and molecular weight of the block copolymers that were expected to incorporate compositions that would form continuous PAN phases prior to carbonization.

TABLE 4
Composition and molecular weights
of PBA-b-PAN block copolymers.^{a}

| polymer | DP of BA | DP of AN | PAN wt % | M_{w}/Mₙ |
|---|---|---|---|---|
| P-1 | — | 90 | 100 | 1.08 |
| P-2 | 89 | 84 | 28.1 | 1.20 |
| P-3 | 70 | 99 | 36.9 | 1.25 |
| P-4 | 90 | 159 | 42.2 | 1.25 |
| P-5 | 90 | 215 | 49.7 | 1.27 |

^{a}DP: degree of polymerization; BA: n-butylacrylate; AN: acrylonitrile; M_{w}: weight average molecular weight; Mₙ: number average molecular weight.

The resulting CTNCs were labeled as C-1, C-2, C-3, C-4 and C-5 after carbonization of block copolymer samples P-1, P-2, P-3, P-4 and P-5, respectively. The morphology of BCPs was first confirmed by atomic force microscopy (AFM) in the form of thin films and samples P2, P3, P4, and P5 showed cylindrical, bicontinuous, bicontinuous, and lamellar morphology, respectively.

Surface area and porosity parameters of CTNCs were obtained through standard N₂ sorption method and small angle X-ray scattering (SAXS) and the corresponding PSDs calculated from Barett-Joyner-Halenda (BJH) method using the desorption branch, respectively. Samples C3, C4 and C5 are found to be type IV (based on IUPAC 1985 classification) since they exhibited typical hysteresis loops. This can be ascribed to the filling and emptying of the mesopores by capillary condensation. The PSDs also indicated the presence of mesopores and the mean size of the mesopore increased with the size of the sacrificial block. Namely, n-butyl acrylate with DP=70 resulted in formation of pores with a mean pore size ˜10 nm (C-3) while pores of ˜18 nm were formed from PBA segments with DP=90 (C-4 and C-5). Therefore it would be expected that higher DP would lead to larger pores and, reciprocally, higher DP of the PAN phase would lead to thicker walls. These results demonstrate the tunability of mesopore size that can simply be achieved via changing the DP of the sacrificial block.

Porosity parameters of these studied carbons are summarized in Table 5, together with the capacitance values.

TABLE 5
Porosity and structural parameters of CTNCs.

| | | | | | | Total pore | characteristic length | | | capacitance |
|---|---|---|---|---|---|---|---|---|---|---|
| | surface area (m²/g) | | | | | volume (cm³/g) | (nm) | | | (F/g) |
| CTNC | S_{BET} | S_{mic}^{a} | Sₘₑₛ^{b} | S_{3.5-50}^{c} | S_{SAXS}^{d} | Vₜₒₜ^{e} | dₚₒᵣₑ^{f} | d_{Bragg}^{g} | d_{carbon}^{h} | C_{g} |
| C-1 | 70 | 46 | 8 | — | — | 0.060 | — | — | — | — |
| C-2 | 196 | 140 | 54 | 43 | 58 | 0.157 | — | — | — | 45 |
| C-3 | 498 | 111 | 226 | 202 | 163 | 0.668 | 10 | 23 | 13 | 166 ± 5 |
| C-4 | 517 | 309 | 213 | 189 | 165 | 0.995 | 18 | 27 | 9 | 173 ± 7 |
| C-5 | 405 | 270 | 138 | 123 | 120 | 0.751 | 18 | 32 | 14 | 151 ± 7 |

^{a}micropore surface area obtained from t-plot method,
^{b}mesopore surface area obtained from BJH method using a desorption branch,
^{c}mesopore surface area having diameters between 3.5 nm and 50 nm obtained from BJH method,
^{d}surface area obtained from the Porod analysis of SAXS patterns,
^{e}total pore volume determined at 0.99 of relative pressure,
^{f}mean mesopore diameter,
^{g}domain spacing calculated from SAXS Bragg peak, and
^{h}carbon wall thickness.

C-1 showed low S_{BET}=70 m²/g with negligible mesopore surface area (Sₘₑₛ) and C-2 showed S_{BET}≈200 m²/g with Sₘₑₛ≈50 m²/g. C-3 and C-4 exhibited similar S_{BET}≈500 m²/g and Sₘₑₛ≈200 m²/g, while C-5 showed S_{BET}≈400 m²/g with Sₘₑₛ=125 m²/g. This indicates that ˜40 wt % of PAN is the most appropriate ratio in PBA-b-PAN copolymers for maximizing surface area of the porous CTNCs due to its bicontinuous morphology providing an optimal 3-dimensional preservation of the porous nanostructure template by the phase separated precursor copolymer. The higher total pore volume (Vₜₒₜ) of C-4 and C-5 over C-3 can be attributed to the larger mean pore size resulting from longer sacrificial PBA block size. Additionally, it should be noted that CTNCs (particularly in C-3, C-4 and C-5) contained a considerable amount of micropores, obtained using the t-plot method, which might be formed from structural imperfections of a phase separated block copolymer or local collapse of carbon matrix during the pyrolysis. However, the collapse of cylindrical and lamellar structures results in smaller surface area. Nevertheless these “collapsed” nanostructured carbons would be expected to retain the desired nitrogen atoms on the surface of the particles and would find use in applications where “ground” carbons are desired such as electrodes for supercapacitors, ORR catalysts and catalysts for water reduction or hydrogen evolution as the formed nanostructures are already well defined nano-scale materials. Even these individual nanostructured carbons could provide materials with increased activity for certain applications by “ball milling” the particular materials to generate improved access to the active edges of the nanographitic domains.

One complication, and unique feature, of the phase diagram studies of PAN containing copolymers stems from partial crystallinity of PAN, which may be of importance in subsequent graphitization. Therefore, PAN-b-PBA with different segment chain lengths and volume fractions were synthesized to cover the full phase diagram and the effect of crystallinity in the PAN phase on the morphology and the formation of “stacked” nanographitic domains was explored by various characterization techniques including differential scanning calorimetry (DSC), small/wide angle X-ray scattering (SAXS/WASX) and tapping mode atomic force microscopy (AFM). The level of nano-structural preservation can be evaluated by SAXS and N₂ adsorption/desorption isotherm. Porod analysis of scattering data can also be used for the calculation of interfacial area before and after pyrolysis.

### Electrocatalysis for Oxygen Reduction Reactions (ORR) Using CTNCs.

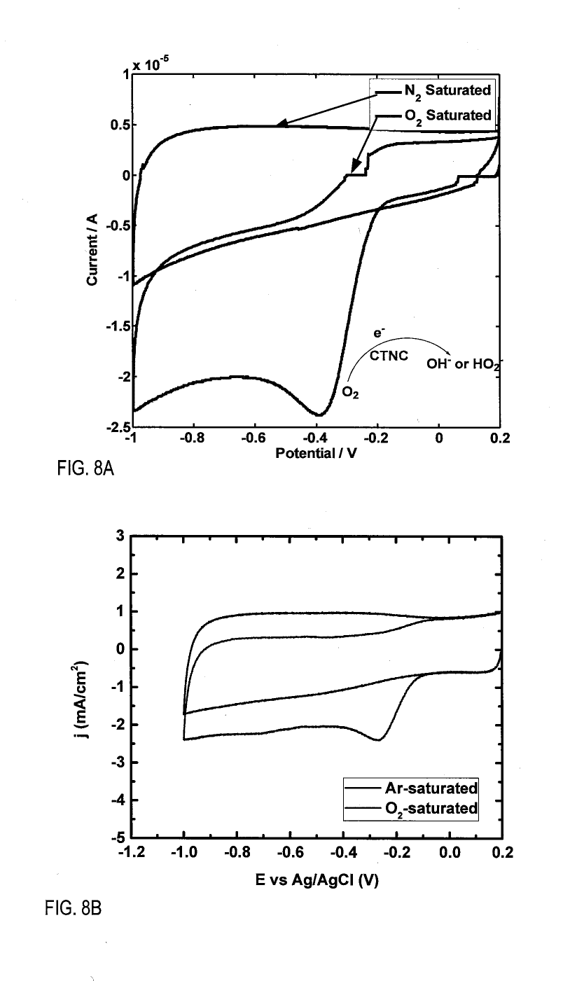

Further confirmation of high electrochemical activity stemming from the presence of “edge nitrogens” came from experiments in which the CTNCs were used as electrocatalysts for oxygen reduction reactions (ORR), which is the crucial and rate-determining process in conversion of chemical to electrical energy in fuel cells. Currently, the most widely used ORR catalysts are Pt-based electrodes which are highly efficient, but suffer from some drawbacks such as time dependent drift in activity and CO deactivation. These drawbacks, and cost considerations, have driven considerable efforts focused on non-precious metal (Science 2009, 324, 71-74 and Science 2011, 332, 443-447) or non-metal based electrocatalytic systems (Ang. Chemie 2011, 50, 5339-5343) for ORR. In the non-precious transition metals procedures the transition metals (e.g. Fe, Co) are typically placed on a carbon catalyst support which, in order to facilitate good binding, is doped with electron-donor heteroatoms (i.e. nitrogen). Weakening of the O—O bond and subsequent O₂ reduction is facilitated in these systems by charge transfer from the electron-rich metal center to the O₂π* orbital (J. Phys. Chem. 1987, 91, 3799-3807). Control experiments with “classic” nitrogen enriched carbon supports revealed that they can exhibit some electrocatalytic activity even in the absence of metal. Given the already mentioned abundance of pyridinic nitrogen heteroatoms in the CTNCs whose synthesis is detailed herein, these materials could be promising candidates for metal free ORR catalysis. This was indeed confirmed by cyclic voltammetry experiments, in which traces taken in the presence of O₂ revealed a pronounced feature at −0.426 V, which can be ascribed to an ORR, FIG. 8A. This demonstration of electrocatalytic activity of the synthesized CTNCs provides further evidence of high electrochemical availability of pyridinic nitrogen in these materials, and represents another surprising result from these studies.

Generally, there are two potential electron transfer process pathways for an ORR, as illustrated below: a four-electron process, which is desired in fuel cell applications due to its high efficiency; and a two-electron process, one generating a H₂O₂ intermediate, which shows other promising applications in glucose sensor and industrial production of H₂O₂.

O₂+2H₂O+4e⁻→4OH⁻ Four-electron pathway:

O₂+H₂O+2e⁻→HO₂⁻+OH⁻

HO₂⁻+H₂O+2e⁻→3OH⁻

2HO₂⁻→2OH⁻+O₂ Two-electron pathway:

The second ORR pathway should be influenced by the carbon nanostructure and heteroatom functionality which, as disclosed herein, can be tuned by pyrolysis temperature, time, and environment, and other stabilization or cross-linking procedures, block copolymer ratio and polydispersity of one or more segments in the copolymer (Macromolecules 2008, 41, 5919), in addition to other templating methods that could provide more controlled orientations of graphitic domains in carbons targeted to device levels for applications including fuel cells, H₂O₂ production and biosensors.

A second approach to form carbons suitable for an ORR reaction took advantage of a novel approach to template N-doped carbons directly from PAN. An aqueous ZnCl₂ was used to disperse 8 nm silica NPs in a solution of low MW PAN (DP˜50). Then, the water was removed by freeze-drying and as-prepared composite was stabilized and pyrolyzed at 800° C. Then, silica was etched by HF, which should also remove the ZnCl₂. Most importantly, the resulting carbon exhibits surface area of 1218 m²/g with, expected, well-defined mesopores of ˜8 nm in diameter. An electrode was prepared and ORR was then performed in 0.1 M KOH with active material on glassy carbon disk as a working electrode, graphite counter electrode and Ag/AgCl reference. FIG. 8B shows CV scans for Ar-saturated and O₂-saturated solutions recorded at 100 mV/s and shows the presence of a strong cathodic peak at 0.75 V vs reversible hydrogen electrode (RHE) in an O₂-saturated electrolyte, but expectedly show no response in the same potential range in Ar-saturated electrolyte. This indicates that the high surface area silica templated carbon has definite electrocatalytic activity toward ORR, The material's high activity for ORR is gleaned from its high positive onset potential value of ˜0.96 V vs RHE and half-wave potential (E_{1/2}) value of ˜0.74 V vs RHE. These values are comparable with those of Fe/Ni-containing N-doped carbon nanotubes, which are recently reported as among the best ORR electrocatalysts. The procedure was repeated with silica particles with 4 nm diameter and the formed carbon displayed a BET specific surface area of the nanoporous carbon was equal to 760 m²/g, and the total pore volume was equal to 0.759 cm³/g. The pores exhibited quite narrow size distribution and the peak on the pore size distribution (PSD) was centered at about 4.2 nm.

PAN is also soluble in aqueous solution containing 50% NaSCN in addition to 60-70% ZnBr₂ so these salts would also work to generate an aqueous solution of PAN capable of forming templated functional carbons.

### Calculations Demonstrating the Ability for Bandgap Control.

According to one embodiment, pyrolysis of the precursors of functional nanocarbons the formation and retention of heteroatom non-bonding edge states are of critical importance for incorporating the desired functionality into CTNCs, e.g. by adding to pseudocapacitance and facilitating electrochemical reduction processes, such as ORR. The purpose of preliminary tight binding calculations described in this section was to establish the extent to which the edge states are affected by the changes of the electronegativity of edge sites, mimicking the presence of edge heteroatoms such as nitrogen.

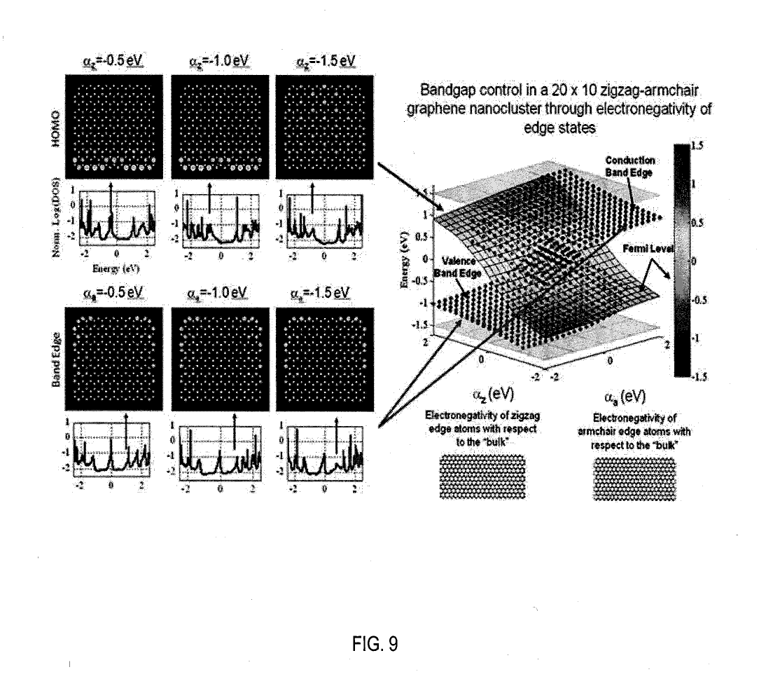

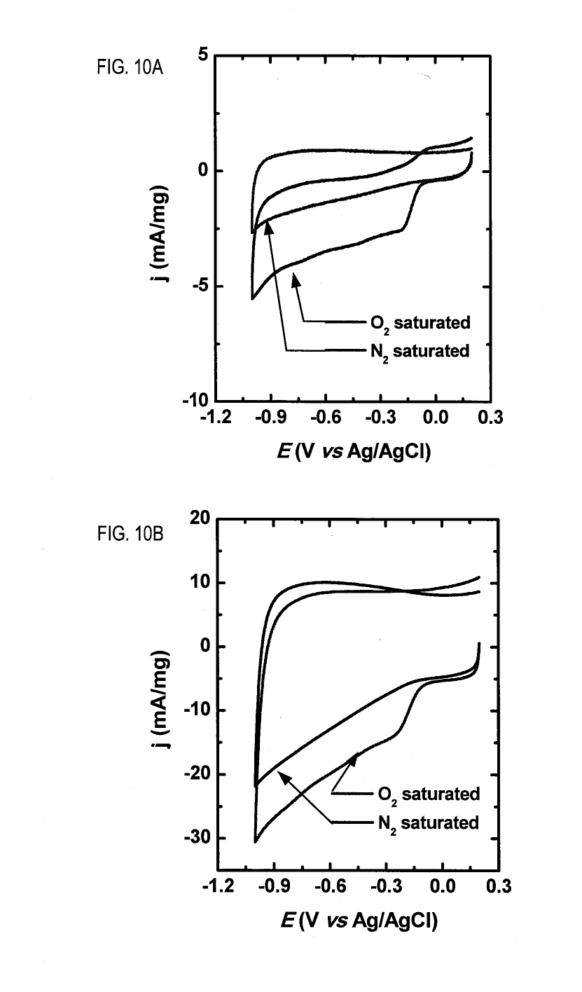

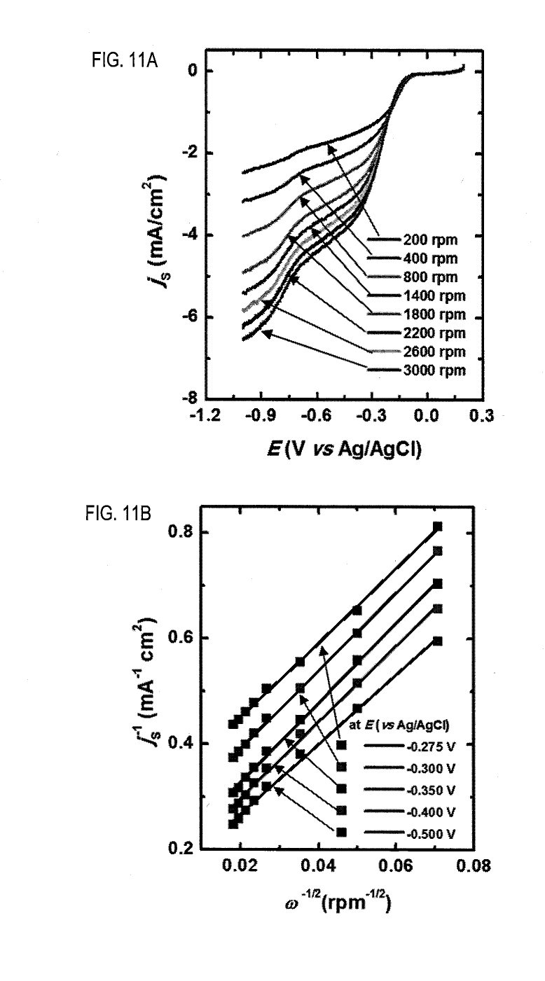

FIG. 9 shows calculated plots of the density of states of a graphene ribbon that has zigzag edges along the top and bottom and armchair edges along the sides. Plots in the top row show the effect of changing the electronegativity of the zigzag edges; the bottom row corresponds to modification of the armchair edges. The zigzag edge states are manifested in these plots as strong peaks at the Fermi energy. The most pronounced effects come from modifications to the zigzag edge, (α_{z}) as shown in the upper left-hand panel. As α_{z} is increased, the localized states, and thus the Fermi energy, increases and eventually merges into the conduction band. Similarly, decreasing α_{z} causes a shift of the Fermi energy peak toward the valence band. Modifying the armchair edges, (αₐ) leads to a different effect, consisting of a shift in either the conduction or valence band edge. A positive αₐ raises the valence band edge, leaving the conduction band essentially unchanged, while a negative αₐ lowers the conduction band edge with little effect on the valence band. The right-hand panel shows the interplay between the effects of substitution on the two edges, illustrating that the combination allows flexible control over the position of the Fermi level relative to the bands. The main outcome of these calculations, which is of importance to the applications discussed herein, is the prediction that non-bonding zigzag edge states should be retained upon the substitution of edge carbons with heteroatoms, and that the main effect of such substitution is a shift of their energy.

The states at the Fermi level continue to be primarily localized on the edges, although some mixing into states within the sheets is observed. These results suggest that states near the Fermi level have substantial populations of heteroatoms that line the nanopores of materials prepared by the treatments disclosed herein. This is a key aspect of the formed electron structures that enables the functionalized nanoporous carbons to be utilized in the proposed applications.

Heteroatom substitution may alter the geometry of the edges, especially for larger elements such as phosphorus. Such structural effects can be examined through DFT calculations on medium-sized model compounds thereby providing information on the impact of the atoms size on the electronic structure when the heteroatom is incorporated into a CTNC. Since the lone pairs on the heteroatoms are of central interest, the models must include both π and π electrons, and that includes electron-electron interactions. A semiempirical models such as the Parriser-Parr-Pople (PPP) and Zerner's Intermediate Neglect of Differential Overlap (ZINDO), which have a long history of success in predicting the properties of conjugated organic molecules and materials was used to enable such calculations on these large systems. To help insure reliable results the model parameters were adjusted to take into account the results from DFT calculations of the band structure of periodic graphene ribbons and the electronic structure of medium-size model compounds.

### Details for Calculating the Koutecky-Levich Plots.

The Koutecky-Levich plots and the kinetic parameters of ORR can be analyzed on the basis of the Koutecky-Levich equations:

$$\begin{matrix}\frac{1}{j} = \frac{1}{{j}_{L}} + \frac{1}{{j}_{K}} = \frac{1}{B {ω}^{1 / 2}} + \frac{1}{{j}_{K}} & ( 1 ) \\ B = 0.62 {nFC}_{0} {D}_{0}^{2 / 3} {v}^{- 1 / 6} & ( 2 ) \\ {j}_{K} = {nFkC}_{0} & ( 3 )\end{matrix}$$

where j (mA/cm²) is the measured current density, j_{K} and j_{L} (mA/cm²) are the kinetic- and diffusion-limiting current densities, ω is the angular velocity of the rotating disk (ω=2πN, N is the linear rotating speed in rpm), n is the overall number of electrons transferred in ORR, F is the Faraday constant (97485 C/mol), C₀ is the bulk concentration of O₂ (1.2×10⁻³ mol/L), D₀ is diffusion coefficient of O₂ (1.9×10⁻⁵ cm² s⁻¹), v is the kinematic viscosity of the electrolyte (0.01 cm² s⁻¹), and k is the electron transfer rate constant, respectively. According to the Equations (1) and (2), the number of electrons transferred (n) and the kinetic-limiting current j_{K} can be obtained from the slope and intercept of the Koutecky-Levich plots (1/j versus ω^{-1/2}). Based on this equation and FIGS. 10A and 10B, the n value for the carbon in KOH (0.1 M) is 3.93.

### Catalysts for Carbon Dioxide Reduction.

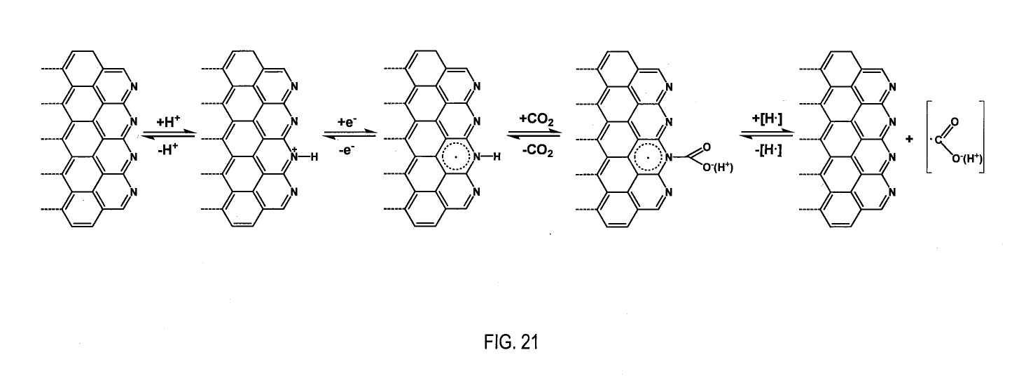

Another important target for the calculations was to determine the nature of the lone-pairs on the heteroatoms. The redox properties of the material, such as those discussed with regards to preparing catalysts for CO₂ reduction, rely on the lone pairs of the heteroatoms retaining their Lewis base behavior, and having sufficient coupling to the electronic states of the carbon sheet that the electrons needed for the reduction reactions can be readily supplied by the external electrodes. Bocarsly et al. discovered the electrocatalytic activation of carbon dioxide in an acidic solution of imidazole and pyridine in the presence of a metal semiconducting electrode (J. Am. Chem. Soc. 2008, 130, 6342 and 2010, 132, 11539). These observations motivated us to determine whether the novel CTNC disclosed herein, i.e. pyridine-rich conjugated systems, can achieve the same purpose. Two approaches were evaluated: (1) the nanographitic particles described above were tested as uniformly dispersed catalysts, where they are expected to play a similar role to that of pyridine in Bocarsly's procedure, although the larger delocalized electron states in nanographene are expected to lower the barrier for electron transfer thereby providing a more effective reduction process; and (2) preparation of a porous nanocarbon based electrode to replace the metal based semiconductor as it is expected that the “aromatically” attached pyridine on such a carbon electrode will undergo faster electron transfer, since the catalyst and electrode would have much more efficient communication compared to current distributed catalysts (see FIG. 21). Furthermore the non-bonding character of the π electrons on the pyridinic edge of the nanographitic domains could enhance the rate of electron transfer. The kinetics and amount of product generated were measured and analyzed by gas chromatography-mass spectrometry (GC-MS)

This aspect of the electronic structure can also be explored through a combination of DFT calculations on medium-sized model compounds, and semi-empirical calculations on large systems. The presence of non-bonding electrons can provide magnetic properties which leads to special physical and chemical properties.

### Introduction of Other Heteroatoms.

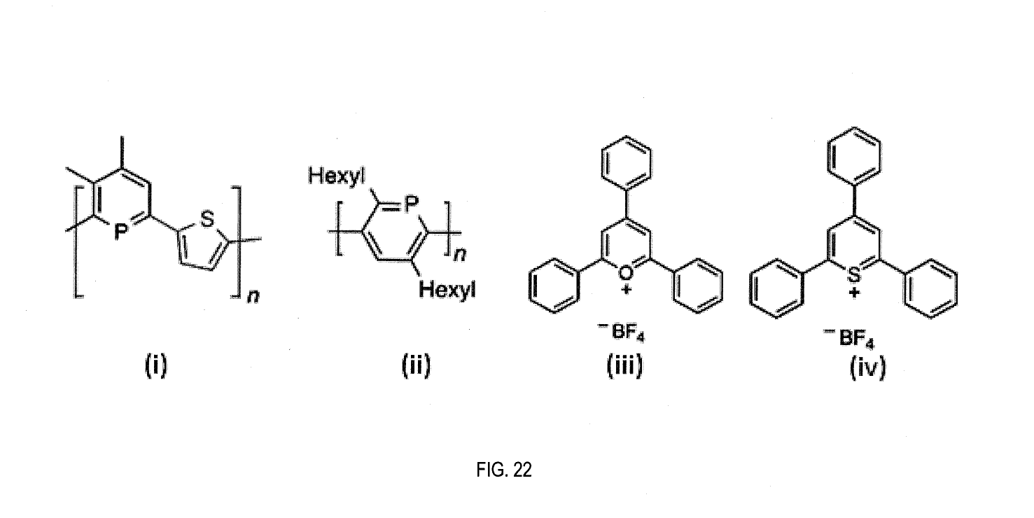

As noted above other heteroatoms can serve as a source of additional functional diversity of nanocarbons. Indications of what can be expected in this regard can come from considerations of other six-membered low molecular weight ring aromatic heterocycles. Some initial candidates for this direction are shown in FIG. 22.

For example, when the nitrogen in the formed pyridine ring is replaced by phosphorus, the overall topology of molecular orbitals shown in FIG. 1 will be retained, however this time the lone pair is more tightly bound by the heteroatom, and the highest occupied molecular orbital (HOMO) is comprised of π-electron, making phosphabenzene a π donor type of a ligand. Furthermore substitution with group 6 elements, results in the formation of pyrylium (oxygen) and thiopyrylium (sulfur) salts (FIG. 22, iii-iv) (Topics in Heterocyclic Chemistry 2009, 19, 203-246). These conjugated structures have interesting optical and emissive properties, they are commercially available and are found as dye pigments in plants. They have also been investigated extensively from an organic chemistry perspective and they are well known to undergo exchange reactions with nucleophiles to form pyridines. However, doping of graphene structures with phosphorus and sulfur has not been pursued nearly as frequently as nitrogen doping, although there are already some useful precedents for phosphorus doped carbons (J Am Chem Soc 2010, 132, 6294). Interestingly, phosphorus doped graphene has been shown to exhibit electrocatalytic activity for ORR, similar to that observed in the nitrogen doped systems (Angew Chem Int Edit 2011, 50, 3257-3261). Based on the teachings disclosed above it would be expected that incorporation of phosphorous, or other noted heteroatoms, into the porous functional nanocarbons disclosed herein would result in stabilized functional carbons comparable to carbons functionalized by doping but displaying increased activity in the targeted applications.

Indeed it is envisioned that new electronic devices will result from this work generating functional materials that will fulfill roles in high performance applications such as sensors for security applications and high temperature, lower weight power electronics for high efficiency energy conversion and storage. Likewise, the low process energy consumption and lower costs for large area electronic devices such as photovoltaics may finally help to make electronic solar energy viable bringing inexpensive power, electronics, and communications to remote areas.

### Metal-Free Electrocatalysts for Dye-Sensitized Solar Cells.

In the case of improvements in solar cells one can utilize the CTNCs as low charge-transfer resistance highly stable alternatives to platinum cathodes in dye-sensitized solar cells. SEM images of a fluorine-doped tin oxide (FTO) patterned glass were spray coated with CTNCs to create a uniform coating of carbon. Importantly, the CTNCs retained their nanostructure during dispersing and spray coating, yielding a high surface area coating on the FTO generating a series of copolymer-templated N-enriched nanocarbons (CTNCs) with well-controlled porosity and nitrogen-heteroatom enrichment that were shown to be efficient, metal-free electrocatalysts for dye-sensitized solar cells (DSSCs) based on the Co(bpy)₃^{2+/3+} redox couple with charge-transfer resistance significantly lower than platinum (0.31 vs. 1.35′Ωcm²). The CTNC-based DSSCs showed better electrochemical stability than platinum and other N-doped carbon-based devices under prolonged potential-cycling, which can be attributed not only to formation of carbons with three-dimensional hierarchical pore structures with high surface area, but also to the presence of site specific covalent N-doping in carbon framework.

In the case of solar cells one can select preparation of carbon particles or carbon rods by selecting phase separated precursor copolymers with spherical or cylindrical morphologies of the carbon precursors prior to thermal stabilization and pyrolysis or silica templates with spherical or cylindrical pores for the templating reaction. Indeed silica particles could be employed to introduce macro-/meso-/micropores into the carbons discussed herein simply by using them as colloidal templates for the block copolymer templates (Chem. Mater. 2011, 23(8): 2024-2026).

### Alternative Approach to Porous Carbons.

An alternative route to incorporate meso- and macro-pores into the final nanostructured carbon is to use a non-solvent as a secondary source of pores. An exemplary example is provided by the preparation of a PAN-b-PBA high internal phase emulsion (HIPE) as the structured carbon precursor. Pluronic F-108 was the best of the commercially available surfactants that stabilized AN/DMF external phase and hexadecane internal phase emulsions. Initial work examined conditions for the preparation of a PAN HIPE. The addition of a PBA macroinitator was then evaluated for the preparation of PAN-b-PBA HIPE to determine if the macroinitiator would destabilize the HIPE. However it was believed that the PBA would help to solubilize PAN for longer amounts of time thereby providing a more homogeneous external phase as PAN is not soluble in AN, so it tends to precipitate at low conversion (˜10-20%), which can cause the formation of very brittle polyHIPE materials. However the reverse procedure chain extension from a PAN macroinitiator, or a macroinitiator with a short PSAN segment, would overcome this limitation and provide sufficient fraction of styrene chain ends for chain extension with BA and formation of HIPE phase separated segmented block precursor that generated pores of nano- to macro-dimensions after stabilization and pyrolysis.

### Photocatalytic Water Reduction.

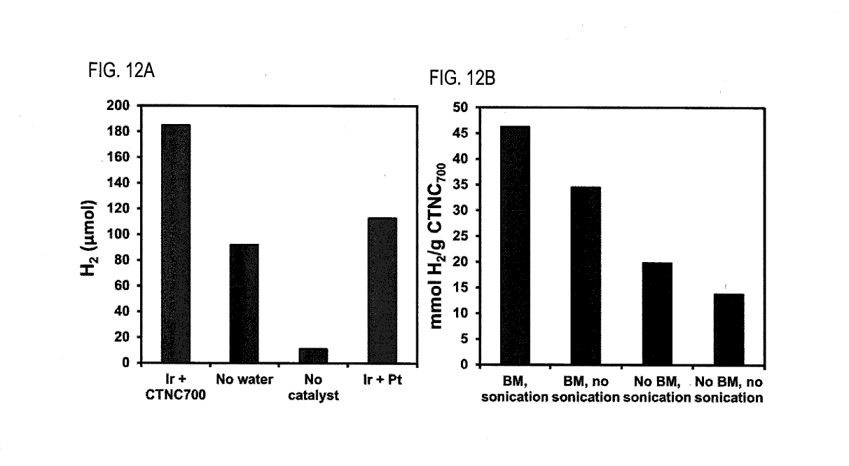

As mentioned above one approach to smaller carbon structures is through physical means such as by grinding or ball milling the first formed carbon structures. One embodiment of the invention is exemplified by formation of carbon structures formed by stabilization and pyrolysis of block copolymers with DP of the PAN segment 140 and DP of the sacrificial PBA segment=90 was stabilized at 280° C. under air flow then the sample was purged with nitrogen during cooling to room temperature over 1 hour prior to pyrolysis at 600-1000° C. under a nitrogen atmosphere over 0.5 hr. The samples were then ball milled for 5 minutes to increase the surface area of the sample which were stored under vacuum at 200° C. prior to being evaluated as components for a metal free photocatalytic reducing catalyst. Surprisingly, as shown in FIG. 12A, it was observed that CTNCs evolved more H₂ than in-situ generated colloidal Pt WRC used under similar conditions. This unexpected observation could be attributed to increased surface area or could be associated with exfoliation of the stacked nanographitic sheets exposing a functionalized nano-graphite sheet.

Negligible amounts of H₂ were evolved in the absence of PS, catalyst, or TEA, indicating that all components are required for the reaction to take place efficiently, providing evidence of a catalytic cycle. Ball-milling (BM) and sonication were carried out to ensure that the performance was not limited by settling of CTNC out of the solution. The nitrogen incorporated in a carbon lattice can create permanent dipoles, which could possibly improve wettability, which may consequently aid in keeping the CTNC well-suspended. As shown in FIG. 12B, samples subjected to both ball-milling and sonication evolved larger quantities of H₂ than without one or both steps. Smaller particle sizes afforded by ball-milling after pyrolysis facilitated suspension of the sample during the prolonged sonication process. This subsequently may have enhanced interaction with the molecular constituents, especially the PS, assisting in more efficient electron transfer and better catalytic performance. Post-reaction XPS analysis of the CTNC revealed the presence of non-metallic iridium within the carbon, corroborating the existence of an improved PS-WRC interface in which the PS may be adsorbed into pores of the CTNC.

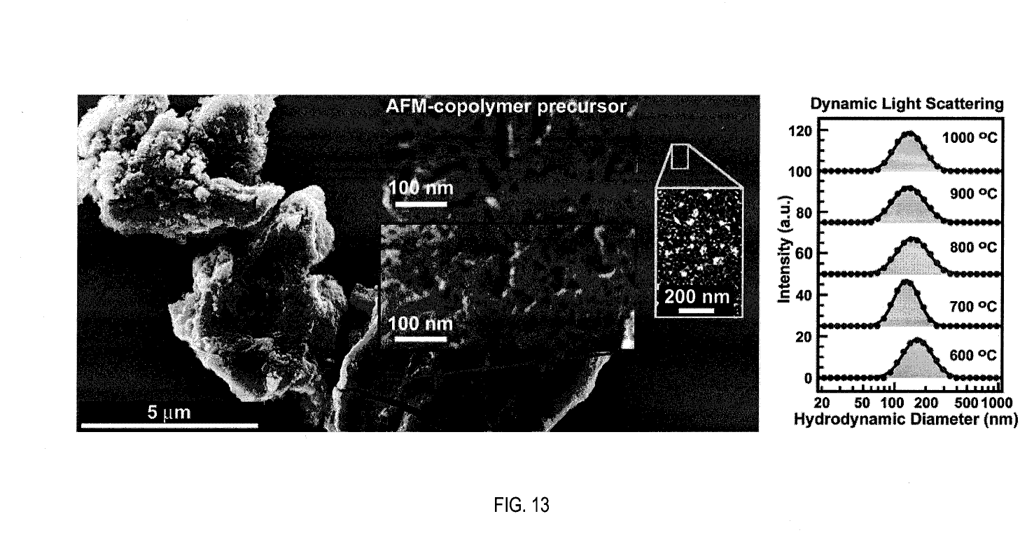

In order to gain further insights into the morphology of ball-milled nanocarbons, deposits of dried suspensions were analyzed by SEM (FIG. 13). The images revealed the presence of micron sized particles (left) with characteristic bicontinuous nano-texture (middle inset, bottom) templated after copolymer morphology (middle inset, top). In addition, all images showed noticeable amounts of sub-100 nm, relatively uniform particles (right inset), which were also evident in DLS of dispersions passed through a 200 nm filter (FIG. 13). Note that particle sizes shown in DLS plots correspond to hydrodynamic diameters and, as such, do not exactly correspond to sizes inferred from SEM images. Remarkably, even though the mass fraction of nanoparticles turned out to be below the detection limit of gravimetric measurements (˜1 wt. %), the filtered suspensions were still highly active, producing an amount of H₂ corresponding to approximately 10% of the output obtained with unfiltered suspensions. Simple mass comparison indicates that the nanoparticle fraction is at least 10 times more active than its micron sized counterpart, which could be attributed to a higher surface to volume ratio or to the presence of a stacked nanographitic domains formed from crystalline domains in the phase separated PAN. Thus, increasing the fraction of nanoparticles appears as a straight-forward strategy to further increase the already high catalytic activity of ball-milled CTNCs in all mentioned catalytic procedures.

### Hydrogen Evolution Reaction.

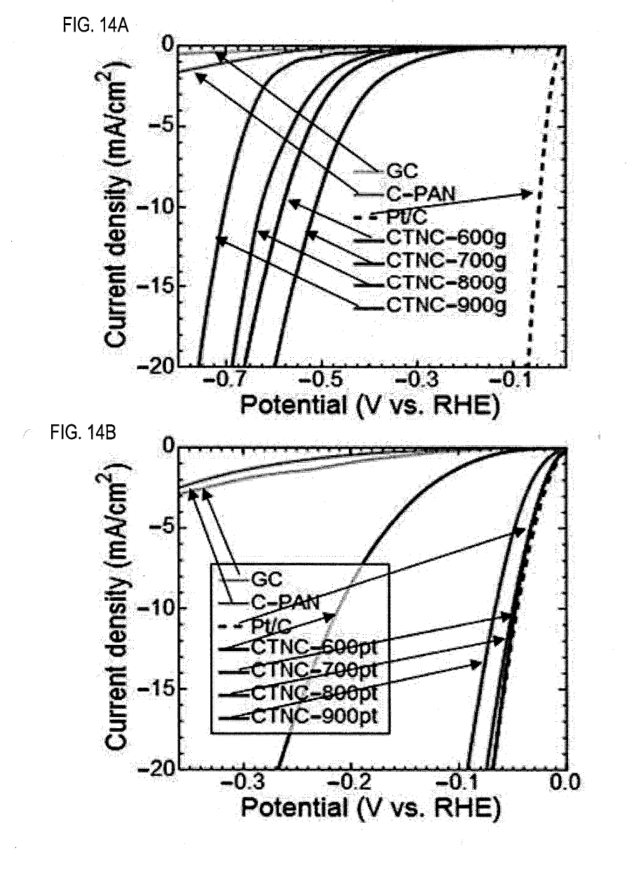

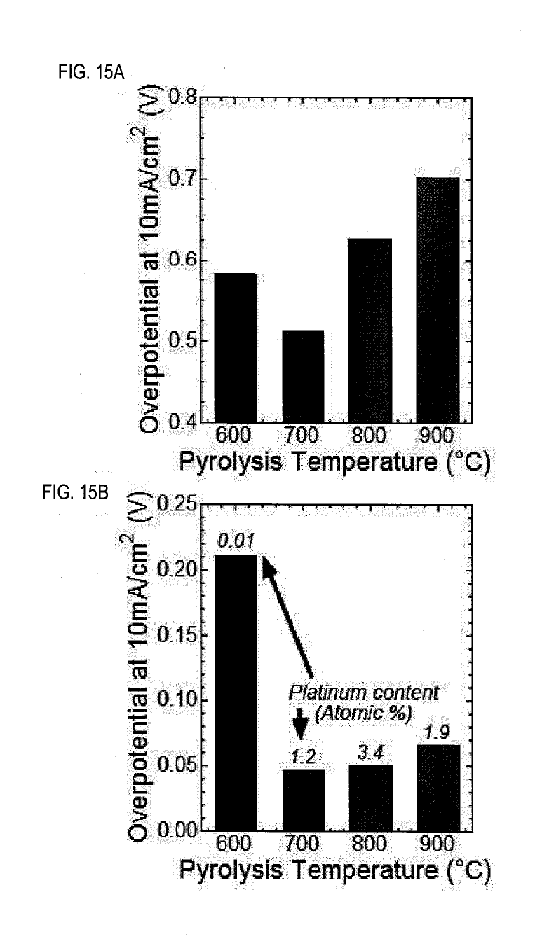

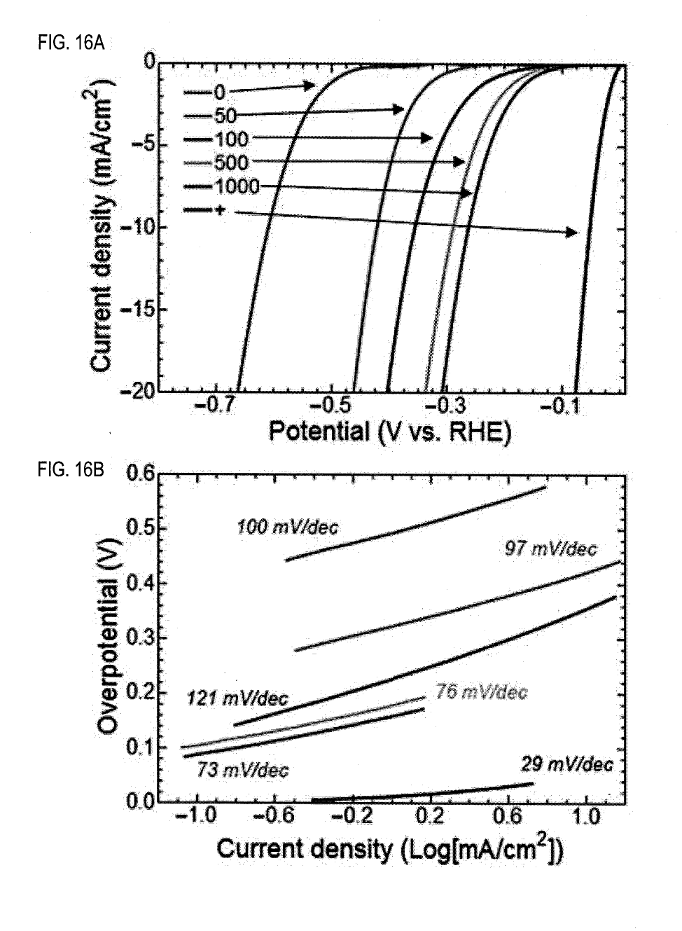

The results of electrochemical experiments with CTNCs under metal-free conditions presented herein demonstrate their appreciable HER activity, afforded by their nanostructure and high electrochemical accessibility of N functionalities, FIG. 14A. Furthermore experiments with Pt counter electrodes revealed the CTNCs' high efficiency as Pt deposition substrates, which was manifested in a dramatic improvement of the HER activity, (FIG. 14B). The morphology and chemical makeup of pristine and cycled electrode surfaces were studied by the combination of high resolution scanning electron microscopy (SEM) and X-ray photoemission spectroscopy (XPS). This combination of electrochemical and analytical experiments made it possible to elucidate the role of N functionalities in providing the intrinsic HER activity of CTNCs and in highly effective functionality for Pt adsorption or sequestration (FIG. 15B).

HER activity of CTNC electrodes was studied by recording polarization curves in 0.5 M H₂SO₄. In order to study the effect of nitrogen content and conductivity, four sets of electrodes were prepared by deposition of block copolymer films on glassy carbon substrates, followed by stabilization through oxidative annealing. Stabilized films were then pyrolyzed under N₂ at temperatures ranging from 600 to 900° C. and used as electrodes in a standard HER electrochemical setup. Two sets of experiments were performed to ascertain the impact of Pt on catalytic activity: (i) cycling with a graphite counter electrode, referred to as metal-free conditions, and (ii) cycling with a Pt mesh counter electrode, referred to as Pt-cycling. In order to fully equilibrate the system, each experiment involved performing 1000 cyclic voltammetry (CV) scans, followed by recording of linear sweeping voltammograms (LSV).

As shown in FIG. 14A, CTNCs cycled with a graphite rod counter electrode exhibited considerable electrochemical activity in comparison to a bare glassy carbon electrode and N-doped carbon prepared by pyrolysis of commercial PAN homopolymer. This comparison indicates that electrochemical activity of CTNCs prepared by the disclosed process is rooted in the combination of N doping and nanostructuring afforded by the copolymer templating method used in their synthesis. Plotting the activity as measured by onset overpotential and overpotential at 10 mV/cm² (referred to as ‘operating overpotential’) against pyrolysis temperature reveals the presence of a clear optimum for materials pyrolyzed at 700° C. with an operating overpotential of about 500 mV. In the discussion of the invention the nanocarbons prepared in this fashion are referred to as CTNC-XXX, where XXX indicates the pyrolysis temperature. The presence of a similar optimum of performance for CTNC-700 g analogues has been observed in the studies of ORR. As in that study, the optimum can be attributed to the interplay between the nitrogen content, density of active sites (see Table 7, below), and the extent of graphitization, and thus electrical conductivity, which, respectively, decrease and increase with the increase of pyrolysis temperature. The paramount importance of nanoporosity of CTNC (surface area 472 m²/g) as a factor providing high number of active sites per unit area of the electrode is reflected by the relatively low HER activity of carbonized PAN homopolymer (surface area 70 m²/g). It should be noted however, that in contrast with ORR, where N-doped carbons, including CTNCs, match the performance of Pt catalysts, no similar match is observed for HER. This can be explained by the different demands of ORR and HER with respect to the proximity of active sites. Specifically, the density of active sites for proton adsorption, pyridinic N atoms, is lower than the density of sites for O₂ adsorption, carbon atoms adjacent to pyridinic N atoms.

Most interestingly, as shown in FIG. 14B, the electrochemical activity of CTNCs increased dramatically when the graphite counter electrode was replaced with a Pt mesh. As in the previous case, the optimum performance was observed for materials pyrolyzed under intermediate conditions (CTNC-700 pt and CTNC-800 pt), but this time it approached the performance of commercial Pt/C catalyst onset potential ˜0 mV vs RHE, operating overpotential <100 mV vs RHE, dashed line in FIGS. 14A and 14D. These results clearly indicate the paramount importance of the CE in investigations of HER activity using new catalysts in acidic media.

One straightforward explanation of the marked increase in HER activity of CTNCs with Pt CE would be some mode of Pt deposition on the CTNC surface. Cycling experiments performed with the CTNC-800 working electrode (FIGS. 16A and 16B for CTNC-600, CTNC-700 and CTNC-900, respectively) revealed that HER activity increased gradually with the number of cycles. The overpotential at 10 mA/cm² shifted from 600 mV vs RHE for pristine electrode to 420 mV vs RHE after only 50 cycles to eventually reach 450 mV vs RHE after 1000 potential cycles. This improvement in performance upon cycling was also evident in the progressive decrease of Tafel slopes, from 100 to 73 mV/dec, FIG. 16B. An even more dramatic effect was observed with only a few additional positive potential scans between −0.8 and +1 V vs SCE, which is sometimes used to prepare electrodes prior to potential cycling (Angew. Chem. Int. Ed. 2015, 54, 4535-4538). The overpotential further decreased to 51 mV vs RHE at 10 mA/cm² (black line, FIGS. 16A and 16B) which is close to the measured performance of commercial Pt/C electrodes. A similar enhancement of HER activity due to Pt deposition on a GC electrode upon very long cycling with Pt CE was recently observed by Dong et al. (Chem. Mater. 2011, 23, 2024-2026). Notably, in the case of CTNC, the gain in activity was observed as early as just after a few cycles. Furthermore, no activity gain was observed in a similar experiment conducted with a graphite CE.

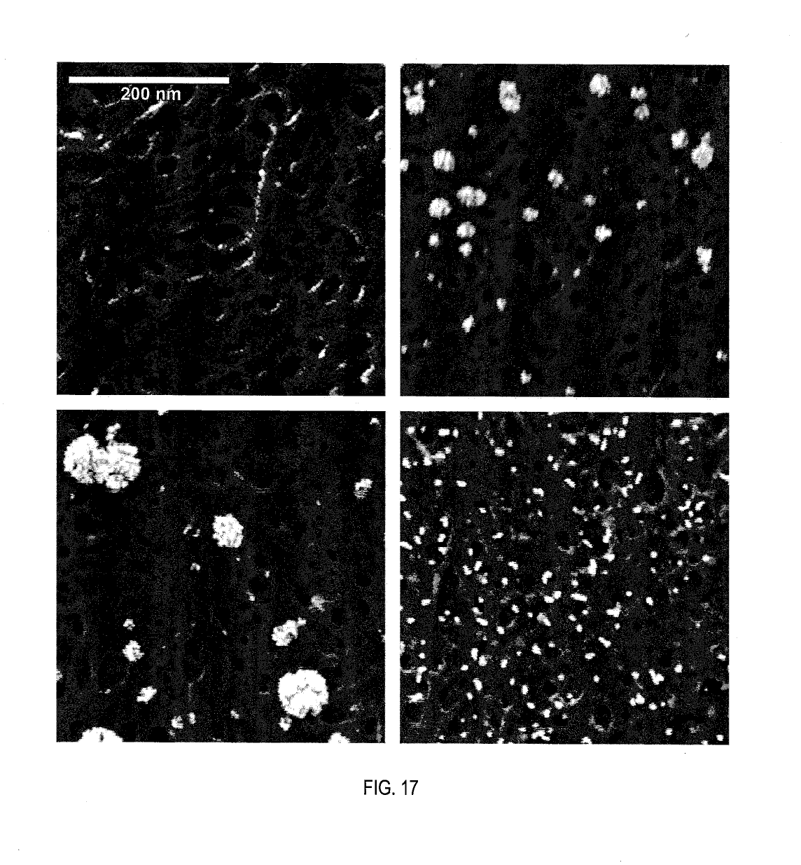

SEM analysis of CTNC electrodes (see FIG. 17), revealed, in all cases, the presence of characteristic nanoscale morphology afforded by BCP templating. Consistent with this templating mechanism, the surface morphology of CTNCs did not appear to change in any significant way with pyrolysis temperature. After cycling, the electrodes became decorated with distinct particulate aggregates, with sizes ranging from a few to tens of nanometers in diameter. Based on EDX and XPS analysis those aggregates were identified as Pt nanoparticles. With the increase of pyrolysis temperature, the initially broad particle size distributions narrowed towards the smallest size to become essentially monomodal for CTNC-900 pt (FIG. 17, bottom right). For CTNC-700 pt and 800 pt, the Pt aggregates appeared to be comprised of smaller nanoparticles assembled into characteristic “cauliflower” structures. Similar structures have been reported by other authors for Pt deliberately deposited on carbon (Int. J. Hydrogen Energy 2011, 36, 15052-15059). The evolution of the size distribution and appearance of aggregates, suggest that their formation proceeds through the nucleation and further aggregation of sub-5 nm nanoparticles.

The presence of such particles is also evident upon the closer inspection of CTNC-600 pt image which, at first glance, appears to be devoid of discernable deposits. The nucleation and growth mechanism can be used to explain the evolution of the abundance and appearance of Pt deposits with pyrolysis temperature of the CTNC substrate. The small amount of Pt deposited on CTNC-600 pt would then be caused by the low nucleation density due to its comparatively lowest electrical conductivity. Conversely, the abundance of Pt nanoparticles on CTNC-900 can be attributed to high nucleation density facilitated by high electrical conductivity. The formation of hierarchical, cauliflower aggregates on CTNC-700 pt and 800 pt could be caused by local electric field concentrations, due to the inhomogeneous connectivity of NG domains forming at these pyrolysis temperatures. Thus, the conductivity of CTNC, which facilitates reduction of Pt-ions, is likely the determining factor for nucleation density.

As demonstrated above, the HER activity of CTNC electrodes with a Pt counter electrode was clearly boosted by Pt deposition. This boost in activity is manifested as a major drop of overpotential between CTNC-600 pt and CTNC-700 pt, concomitant with the observed increase of Pt content near the surface detected by XPS from 0.01 to >1 at. % (FIG. 15B). It is importance to note, however, that CTNCs exhibited considerable HER activity in a metal-free system. Under those circumstances, its most likely origin of activity was the presence of accessible N functionalities, which is widely believed to be the source of activity in N-doped carbons. For example, according to the currently held views, the ORR activity of N-doped carbons is attributed to C atoms adjacent to pyridinic N atoms. Lone pair electrons of these N atoms are in turn pointed to as active sites for HER. Given these observations it is reasonable to expect that the same functionalities also serve as primary deposition sites for Pt atoms, which then effectively supersede N atoms as active sites for H⁺ adsorption.

More insights into the role of N atoms in HER and Pt deposition were obtained through the analysis of high resolution is N and 4f Pt XPS spectra of CTNC electrodes used in electrochemical experiments. The spectra of pristine CTNCs were dominated by two peaks, centered at 398 and 401 eV, FIGS. 7A-D. The lower energy peak corresponds to pyridinic N, and its decrease with the increase of pyrolysis temperature reflects the concomitant decrease of N content which has been widely reported in literature for PAN derived carbons. In contrast, the 398 eV feature is much less discernable in the spectra of Pt-cycled samples, which are dominated by a single feature centered at 400 eV.

The elimination of N—Py from the carbon framework as a cause of diminution of N-Py feature can be ruled out since the overall N content, as determined by survey spectra, remained constant. Conversion of N-Py to N—X (for example through oxidation of adjacent C atoms) can be ruled out as well, since the spectrum of Pt-cycled samples peaks at a binding energy about 1 eV lower than expected for N—X species. An alternative, natural explanation for the shape change of the spectrum of Pt-cycled electrodes is that it is caused by the upward shift of binding energy of pyridinic N atoms upon coordination with Pt atoms. Indeed, the observed shift is in very good agreement with the shift predicted by DFT calculations performed on pyridine and Pt-coordinating pyridine.

One embodiment of the invention disclosed herein demonstrates the impact of nanostructuring on boosting the HER activity of metal-free N-doped carbons. Additionally the high HER activity of cycled CTNCs used herein is paralleled by their high efficiency in sequestration of minute amounts Pt due to trace dissolution of Pt counter electrodes. The ability of CTNC to sequester and bind Pt can lead to the development of novel catalyst supports based on nitrogen-doped carbon that utilize significantly lower amounts of precious metals.

Results of detailed XPS analysis provides strong indication that, in both cases, the high activity of N-doped carbons can be attributed to the presence of pyridinic nitrogens. The high electrochemical availability of these functionalities appears to be facilitated by the copolymer templating method used in the synthesis of CTNCs as seen by the lack of activity in pyrolyzed commercial PAN. One of the possible sources of this availability is molecular orientation of precursor polymer chains, inherent in the copolymer templating process. This aspect of this method points to its potential benefits in synthesis of highly efficient, functional nanocarbons.

### Uranium Sequestration.

The unexpected increase in the HER activity of the first formed CTNCs when cycled with a Pt electrode prompted a question as to whether the first formed CTNCs could sequester other metals. Therefore the uranium separation properties of CTNCs formed by pyrolysis of PAN block copolymers between 500° C. and 900° C. with different structural properties, nitrogen content and status of the nitrogen were studied since uranium adsorption had been successful with an ATRP PAN-functionalized porous aromatic framework (Ind. Eng. Chem. Res., 2016, 55 (15), pp 4125) or an AN and tBA copolymer poly(vinyl chloride)-co-chlorinated poly(vinyl chloride) functionalized fiber (Ind. Eng. Chem. Res., 2016, 55 (15), pp 4130). Indeed the complete Ind. Eng. Chem. Res., 2016, 55 (15) pp 4101-4361 edition was dedicated to procedures being evaluated for uranium adsorption from seawater. Dia et. al. prepared adsorbents with varied composition of amidoxime groups and hydrophilic acrylate groups by ATRP combined with radiation-induced graft polymerization (RIGP) (J. Mater. Chem. A, 2014, 2, 14674-14681). Other potential absorbents including and poly(glycidyl methacrylate) grafted from carbon nanotubes via bioinspired catechol chemistry by some of the present inventors (ACS Macro Letters 2016, 5, 382-386) had also been examined.

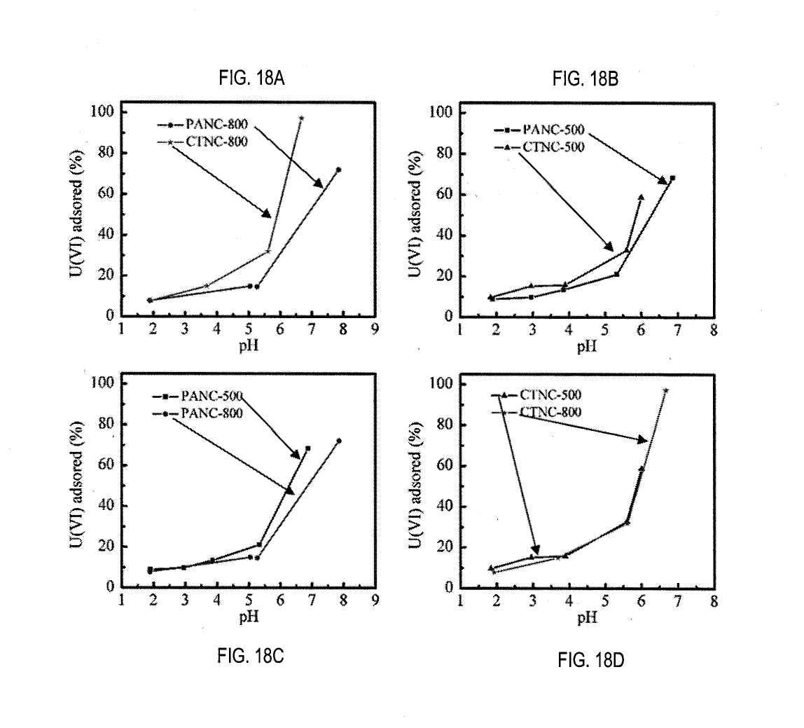

The present CTNC product outperformed these recent prior art products showing the ability of 5 mg of a CTNC to remove 100% of the uranium in a test water sample, containing 100 ppm uranium. Samples of the CTNCs were also compared to carbons formed from PAN (PANC) under the same stabilization and pyrolysis conditions to provide an alternate procedure for preparation of uranium absorption nitrogen functionalized carbons. From FIG. 18A, it can be concluded that N-doped porous carbon possesses an excellent ability for removal of U(VI) from aqueous solutions and essentially 100% of U(VI) was removed by CTNC-800 when pH reached 6.5. Thereby indicating that surface area plays an important role in adsorbing U(VI) at higher pH, since CTNC-800 presents significantly increased adsorption capacities in the pH range of 5 to 6.5 in comparison to PANC-800. Compared to PANC-800, CTNC-800 has over 2 times larger surface area but similar nitrogen content, as shown in Table 8. Therefore, stronger adsorption capacities of CTNC-800 can be attributed to the greater surface area and improved accessibility to the functional nitrogen atoms.

TABLE 8
Structure properties of PANCs and CTNCs

| | specific surface | pore | pore |
|---|---|---|---|
| Samples | area (m²/g) | volume (cm³/g) | size (nm) |
| PANC-500 | 15 | 0.08 | 45.9 |
| PANC-800 | 191 | 0.17 | 10.8 |
| CTNC-500 | 382 | 0.49 | 7.1 |
| CTNC-800 | 421 | 0.49 | 7.4 |

Meanwhile, CTNC-500 and PANC-500 show consistent adsorption results for U(VI) (FIG. 18B). When pH was lower than 5, the differences for removal ratio of U(VI) between PANC-800 and CTNC-800 or PANC-500 and CTNC-500 were very small (FIGS. 18A and 18B). At pH=1.9, PANC-800 and CTNC-800 even presented almost identical removal ratio of U(VI) (7.8%), similar to PANC-500 and CTNC-500 with the removal ratio of ˜9%. This observation indicates that surface area made little contribution to the adsorption of U(VI) at pH=1.9. Therefore, one can conclude that the adsorption of U(VI) at low pH can be mainly attributed to the existence of accessible nitrogen functionalities. The contribution of nitrogen to adsorption is also demonstrated by FIGS. 18C and 18D. In FIG. 18C, PANC-500 presents larger adsorption capacities than PANC-800 in the pH range of 1.9-7, while the surface area of PANC-500 is dramatically lower than PAN-C800, Table 8, and, with the increase of pH value, the difference of removal ratio between PANC-500 and PANC-800 accordingly increased, indicating nitrogen also made larger contribution to the adsorption of U(VI) at higher pH. This phenomenon can account for stronger protonation of nitrogen at low pH, resulting in weaker complexation with U(VI). FIG. 18D shows that CTNC-500 had larger adsorption capacities for U(VI) at low pH due to 4.74% higher nitrogen content than CTNC-800 (see Table 8). When pH increased, both nitrogen and surface area had more important effect on adsorbing U(VI). Therefore, similar adsorption capacities of U(VI) for CTNC-500 and CTNC-800 at pH of 4-6 can be ascribed to larger surface area but lower nitrogen content of CTNC-800. The contribution of nitrogen to adsorption capacity can also be demonstrated by FIGS. 18C and 18D. In FIG. 18C, PANC-500 presents larger adsorption capacities than PANC-800 in the pH range of 1.9-7, while the surface area of PANC-500 is dramatically smaller than PAN-C800 (see Table 8). However, with the increase of pH, the difference of removal ratio between PANC-500 and PANC-800 accordingly increased, indicating nitrogen also made larger contribution to the adsorption of U(VI) at higher pH. This phenomenon can account for stronger protonation of nitrogen at low pH, resulting in weaker complexation with U(VI).

FIG. 18D shows that CTNC-500 had larger adsorption capacities for U(VI) at low pH due to 4.74% higher nitrogen content than CTNC-800 (see Table 9). When pH increased, both nitrogen and surface area had more important effect on adsorbing U(VI). Therefore, similar adsorption capacities of U(VI) for CTNC-500 and CTNC-800 at pH of 4-6 can be ascribed to larger surface area but lower nitrogen content of CTNC-800.

TABLE 9
XPS results of PANCs and CTNCs

| | Element composition (atomic ratio, %) | | | | | | |
|---|---|---|---|---|---|---|---|
| Samples | C | O | N | N/C | N—P | N—X | N—O |
| PANC-500 | 76.88 | 4.47 | 18.65 | 24.26 | 41.07 | 36.64 | 22.29 |
| PANC-800 | 85.50 | 3.38 | 11.11 | 12.99 | 38.15 | 39.33 | 22.52 |
| CTNC-500 | 79.17 | 5.72 | 15.11 | 19.09 | 40.65 | 35.25 | 24.10 |
| CTNC-800 | 86.55 | 3.09 | 10.37 | 11.98 | 36.34 | 38.47 | 25.19 |

### Dye-Sensitized Solar Cells.

The CTNCs were also evaluated as novel, metal-free counter electrodes (CEs) for dye-sensitized solar cells (DSSCs). The CTNCs with well-controlled morphology, nanoporosity, and nitrogen content displayed superior performance due to the high catalytic activity of CTNCs toward the reduction of Co(bpy)₃^{2+/3+}, as evidenced by unusually low charge transfer resistance (RCT) at the CE-electrolyte interface. The observed activity is attributed to the combination of the high surface area of CTNCs afforded by a three dimensional, hierarchical pore structure, and to their unique electronic properties stemming from the presence of nitrogen heteroatoms located on the edges of nanographitic domains. Altogether, the use of CTNC CEs enhanced the efficiency and fill factor (FF) of JK-306 dye, Co(bpy)₃^{2+/3+} redox couple based DSSCs at one sun illumination up to 10.32% and 73.5%, respectively, suggesting the considerable promise of these materials as an attractive alternative to costly Pt-based CEs. This chemical specificity indicates that the type of nitrogen bonding configurations, rather than the total N-content, is the key factor determining the catalytic activity.

### EXAMPLES

The invention is illustrated by the following examples, without the examples limiting the subject matter of the invention.

Characterization of Polymers:

Conversion of monomers was measured by gas chromatography (GC) using a Shimadzu GC14-A gas chromatograph with a FID detector equipped with a J&W Scientific 30 m DB WAX Megabore column. Injector and detector were kept at 250° C. The apparent molecular weights and molecular weight distributions (M_{w}/Mₙ) were determined by gel permeation chromatography (GPC) (Polymer Standards Services (PSS); columns (guard, 10⁵, 10³, and 10² Å), with DMF for polyacrylonitrile (PAN) and poly(butyl acrylate)-block-polyacrylonitrile (PBA-b-PAN) or THF for poly(butyl acrylate)(PBA) eluent at 35° C., flow rate=1.00 mL/min, and differential refractive index (RI) detector (Waters, 2410)) calibrated with linear polystyrene standards using WinGPC 6.0 software from PSS. Toluene was used as the internal standard. Polystyrene standards were employed for the GPC calibration. ¹H nuclear magnetic resonance (NMR) spectra recorded on a Bruker Avance spectrometer (300 MHz) was used to determine the Mₙ of PAN and PBA-b-PAN in DMSO-d6 and DMF-d7, respectively.

X-Ray Diffraction (XRD):

Powder diffraction patterns were performed on a Panalytical X'Pert Pro MPD fitted with a copper radiation source (λ₁=1.5405980 Å, λ₂=1.444260 Å, weighted average λₐᵥₑ=1.54178) and the power settings were 45 kV and 40 mA. Focusing optics were conducted with a nickel filter. A PIXcel detector was used with a graphite crystal with a 5.7 mm anti-scatter slit on the diffracted beam side. Measurements were collected within a 2θ range from 5 to 90° with a step size of 0.2°. The XRD patterns were analyzed and fitted using Matlab to pseudo-Voigt functions for peaks: (002), (10), and corrected for a power slope with a constant baseline. The distance between the two parallel basal planes along the perpendicular direction to basal plane (d₀₀₂) was calculated from the Bragg angle (2θ) at the (002) peak. The crystallite size of the basal plane (Lₐ) and that of perpendicular direction to the basal plane (L_{c}) were calculated from the (10) peak and the (002) peak respectively, using the Scherrer equation. Lₐ and L_{c} were calculated to be ˜2 nm and ˜1 nm, respectively. The average number of stacked layers in the graphitic domains was calculated by dividing L_{c} by d₀₀₂ and its value was ˜2.6.

X-Ray Photoelectron Spectroscopy (XPS):

XPS measurements were performed with a Kratos Axis Ultra spectrometer under the pressure of 10⁻⁸ torr. The monochromatic X-ray source was Al Kα (1486.6 eV) and the power was 208 W (14 kV, 20 mA). The voltage step size was 0.5 eV for surveys and 0.1 eV for high resolution. The dwell time at every step was 150 ms for surveys, 600 ms for 0 and C, and 2000 ms for N high resolution. Quantification was performed by applying the appropriate relative sensitivity factors (RSFs, C 1s=0.297, O 1s=0.703, N 1s=0.491) after subtracting Shirley-type background. The deconvolution into component peaks in high resolution peaks were carried out using 7:3 product of Gaussian-Lorentzian. Binding energy was corrected with reference to C 1s at 285.0 eV.

Small Angle X-Ray Scattering (SAXS) Analysis Using Porod Law:

For an ideal two-phase model with sharp and smooth interfaces and as q→∞, the Porod law predicts that the scattered intensity will vary with q as:

$$I ( q ) = \frac{2 {π ( Δρ )}^{2} S}{{q}^{4}} \qquad ( 1 )$$

where Δp is the difference between the scattering length densities of the two phases and S is the interfacial area.
The scattered intensity can be normalized by an invariant Q defined as:

$$Q = \frac{1}{2 {π}^{2}} {\int }_{0}^{∞} {q}^{2} I ( q ) d q \qquad ( 2 )$$

In the present study, the numerical integration of the azimuthally averaged SAXS patterns was carried out over the range of q from 0.05 to 1.8 nm⁻¹.
According to Porod's model, the invariant is related to the sample volume V and volume fractions of distinct phases φ₁ and φ₂=1−φ₁ by:

Q=V(Δρ)²φ₁φ₂ (3)

Substitution of eq (3) into eq (1) gives:

$$\frac{I ( q )}{Q} = \frac{2 π}{{φ}_{1} {φ}_{2}} \frac{S}{V} \frac{1}{{q}^{4}} \qquad ( 4 )$$

Eq (4), can be also written in the form that does not include the volume fractions of each phase, and uses the length of inhomogeneity l_{P} defined as the geometric average of cord lengths cut through phases 1 and 2 and can be expressed as:

$$\frac{1}{{l}_{p}} = \frac{1}{< {l}_{1} >} + \frac{1}{< {l}_{2} >} \qquad ( 5 )$$

where indices refer to phases 1 and 2 and < > brackets indicate orientational and positional averaging.
According to Porod, the length of inhomogeneity is related to other sample parameters as:

$${l}_{P} = 4 \frac{V}{S} {ϕ}_{1} {ϕ}_{2} \qquad ( 6 )$$

Substitution of eq (6) into eq (4) gives the alternative form of Porod's law:

$$\frac{I ( q )}{Q} = \frac{8 π}{{l}_{P}} \frac{1}{{q}^{4}} \qquad ( 7 )$$

Eq (4) or eq (7) can be used to determine l_{P} or interfacial area per unit volume (S/V or S_{V}) by fitting the invariant-normalized scattering intensity to the q⁻⁴ power law. Note that the calculation of the S_{V} from eq (4) requires the knowledge of the volume fractions of phases 1 and 2.

In the present study, volume fractions of phases within the copolymer precursor were calculated from their known block composition and densities. E. g. if the mass fraction of PAN in block copolymer obtained from NMR spectra was 36.9 wt % it was then converted to the volume fractions (φ_{PBA}=0.646, φ_{PAN}=0.354) assuming that the densities of PBA and PAN phases were equal to the densities of respective homopolymers (ρ_{PBA}=1.09 g/cm³, ρ_{PAN}=1.17 g/cm³). For the carbonized material, calculation of volume fractions of carbon and pores was based on the total pore volume per gram (Vₜₒₜ) obtained from nitrogen adsorption analysis. Vₜₒₜₐₗ was calculated as 0.67 cm³/g based on the amount of nitrogen adsorbed at a relative pressure of 0.99. Conversion of this value to volume fractions of carbon and pores still required the knowledge of density of carbon matrix. This was estimated using the known relationship between the density of carbon materials as a function of the H/C ratio. Using this relationship and the H/C ratio (˜0.20) obtained for the copolymer templated nitrogen-rich porous carbons (CTNC) from elemental analysis, the carbon matrix density was estimated to be equal to ˜1.75 g/cm³. From the Vₜₒₜ and carbon matrix density, the volume fractions of pore and carbon was, φₚₒᵣₑ=0.539, φ_{carbon}=0.461.

Nitrogen Sorption Analysis:

The pore structure of each carbon sample was assessed from the N₂ isotherm curve measured by a gas adsorption analyzer (NOVA2000 series, Quantachrome Instruments). Prior to the adsorption experiments, all samples were degassed at 300° C. for 3 h to eliminate the presence of any surface contaminants (water or oils). The standard analysis of nitrogen sorption isotherms recorded for all samples studied provided the Brunauer-Emmett-Teller (BET) surface area, S_{BET}, evaluated in the range of relative pressure between 0.04-0.2, the micropore surface area, S_{mic}, was evaluated by αₛ-plot analysis, the mesopore surface area, Sₘₑₛ (or S_{3.5-50}), obtained by integration of the dS/dD curve, derived from pore size distributions (PSD) curve expressed as dV/dD vs. pore diameter (D), assuming a cylindrical pore structure) in the range between 2 (or 3.5) and 50 nm, the single-point total pore volume, Vₜₒₜ, evaluated at a relative pressure of 0.99, the mesopore volume having pore diameters in the range between 3.5 and 50 nm, V_{3.5-50}, were obtained by integration of the PSD curve in the aforementioned range, and the pore width, w, at the maximum of the PSD curve, which are summarized in Table 6.

TABLE 6
Adsorption parameters for some of the carbon samples studied.

| | | CTNC | CO₂—A | KOH—A |
|---|---|---|---|---|
| surface area (m²/g) | S_{BET} | 500 | 1140 | 2570 |
| | S_{mic} | 240 | 400 | 1800* |
| | Sₘₑₛ | 236 | 438 | 2156 |
| | S_{3.5-50} | 180 | 263 | 1078 |
| pore volume (cm³/g) | Vₜₒₜ | 0.67 | 1.09 | 2.13 |
| | V_{3.5-50} | 0.54 | 0.71 | 1.47 |
| pore width (nm) | w | 13.3 | 12.9 | 3 |

*Note the αₛ-plot analysis does not provide information about the range of fine pores corresponding to the estimated S_{mic}. Since the PSD curve for KOH—A is in the form of a single peak located in the range of micropores and very small mesopores (around 3 nm), it is difficult to separate the contributions arising from micropores and mesopores; consequently, both S_{mic} (estimated by the αₛ-plot analysis) and Sₘₑₛ (obtained by integration of PSD between 2 and 50 nm) contain some considerable contributions arising from small mesopores (around 3 nm) and their sum exceeded the value of S_{BET}.

The micropore surface area (S_{mic}) was obtained from the αₛ-plot, using reference adsorption data reported by Kruk et. al. (Chem. Mater. 2001, 13, 3169-318).

The standard adsorption αₛ is defined as follows:

$${α}_{S} = \frac{volume adsorbed a t a relative pressure P / {P}_{0}}{volume adsorbed at P / {P}_{0} = 0.4} \qquad ( 8 )$$

The Kruk-Jaroniec-Sayari (KJS) method was used for calculation of PSDs from adsorption branches of nitrogen adsorption-desorption isotherms (J. Colloid. Interface Sci. 1997, 192, 250-256; Langmuir 1997, 13, 6267-6273). This method is based on the Barett-Joyner-Halenda (BJH) calculation algorithm for cylindrical pores (J. Am. Chem. Soc. 1951, 73, 373-380), in which a correction was made in Kelvin equation to eliminate its deviation in the range of small mesopores and an experimental t-curve derived for a reference carbon surface was used instead of original t-curve, as suggested by Jaroniec and co-workers. This modification of the BJH procedure is known as the KJS method.

The process of conversion from S_{3.5-50} to S_{V} is as follows, giving an example of S_{3.5-50}=180 m²/g. The density of carbon was estimated to be 1.75 g/cm³ in a way as shown in a SAXS analysis section and then, the corresponding volume of 1 g of carbon (without any pores) is 1/1.75≈0.57 cm³/g. The total pore volume of the CTNC sample was equal to 0.67 cm³/g. Thus, the total volume (including carbon and pores) of 1 g of carbon would be, 0.67+0.57=1.24 cm³/g, which gave the surface area to volume, S_{V}=(180 m²/g)/(1.24 cm³/g)=145 m²/cm³.

Materials:

Acrylonitrile (AN), n-butyl acrylate (BA), methyl 2-bromopropionate (MBP), 2-bromopropionitrile (BPN), N,N,N′,N″,N″-pentamethyldiethylenetriamine (PMDETA), 2,2′-bipyridyl (bpy), CuBr, CuCl, CuBr₂, anisole, dimethylformamide (DMF), dimethylsulfoxide (DMSO), tetrahydrofuran (THF), N-methyl-2-pyrrolidone (NMP) and methanol were all obtained from Sigma-Aldrich. CuCl and CuBr were purified by stirring in glacial acetic acid followed by washing with ether and dried overnight under vacuum. Monomers were passed through a basic alumina column prior to use. All other chemicals were used as received.

### Example 1: Preparation of PBA Macroinitiator

30 mL of BA (2.10×10⁻¹ mol), 2.24×10⁻¹ mL of PMDETA (1.07×10⁻³ mol), 1.99×10⁻¹ mL of MBP (1.79×10⁻³ mol), 2.0 mg of CuBr₂ (9×10⁻³ mmol), and 15 mL of anisole were mixed in a 50 mL Schlenk flask equipped with a magnetic stirring bar. The flask was subjected to five freeze-pump-thaw (FPT) cycles. Then, 1.28×10⁻¹ g of CuBr (8.93×10⁻⁴ mol) was added to the flask while the contents were at a solid state and deoxygenated by vacuum followed by back-filling with nitrogen three times. The flask was placed in an oil bath set at 70° C. for 5.5 h. The reaction was terminated by the addition of aerated THF and passing through a column of alumina to remove the catalyst followed by evaporation. The solid products were dried in a vacuum oven, providing the desired polymer.

### Example 2: Preparation of PBA-b-PAN Copolymers

1.23 g of the above PBA macroinitiator (1.23×10⁻⁴ mol; Mₙ (GPC)=10,000 and M_{w}/Mₙ=1.10), 2.57 mL of AN (3.96×10⁻² mol), and 4.0 mL of DMSO were mixed in a 10 mL Schlenk flask equipped with a magnetic stirring bar. The flask was subjected to five FPT cycles. Then, 1.22×10⁻² g of CuCl (1.23×10⁻⁴ mol) and 3.85×10⁻² g of bpy (2.46×10⁻⁴ mol) were added to the flask, as above, and purged by back-filling with nitrogen. The flask was then placed in an oil bath set at 65° C. for 7 h. At the end of this time, the reaction mixture was dissolved in DMF, and the polymer was precipitated by adding the solution to 50% aqueous methanol. The solid product was dried under vacuum, yielding the desired block copolymer.

### Example 3: Preparation of CTNC

The polymer sample was stabilized at 280° C. for 2 h under air flow (150 mL/min) with a heating rate of 20° C./min, purged with nitrogen gas for one hour during cooling, and then pyrolyzed at 700° C. for 0.5 h under nitrogen gas flow (150 mL/min) with a heating rate of 10° C./min.

### Example 4: CO₂ Activation of CTNC

The nanoporous carbon sample was heated at a rate of 20° C./min under nitrogen gas flow (150 mL/min) to 900° C. and kept at that temperature under CO₂ flow (150 mL/min) for 1 h. Then, the sample was cooled under nitrogen gas flow.

### Example 5: KOH Activation of CTNC

Deionized water was added to the mixture of KOH and carbon mass at a mass ratio of 4/1 and stirred for 30 min. The slurry was dried at 110° C. for 12 h then heated up to with a heating rate of 5° C./min and kept at 800° C. for 2 h under Ar flow. The resultant activated carbon was rinsed with 0.5 M HCl and repeatedly washed with hot deionized water. The final activated carbon was dried under vacuum at 90° C. for 2 days.

### Example 6: Characterization of CTNC

The mass change during the carbonization was monitored by thermogravimetric analysis (TGA: SDT 2960, TA Instruments). The nanoporous morphology of CTNC was analyzed by transmission electron microscopy (TEM: H-7100, Hitachi). Nitrogen adsorption-desorption isotherms were obtained with an NOVA 2000 (Quantachrome Instruments) at −196° C. The sample was degassed at 300° C. for 2 h before measurement. Elemental analysis was conducted by Midwest Microlab (Indianapolis, Ind.) with a combustion method analyzer (CE-440, Exter Analytical Inc.) and with X-ray photoelectron spectroscopy (XPS, Kratos Axis Ultra spectrometer). Small angle X-ray scattering (SAXS) experiments was carried out at D1 station of Cornell High Energy Synchrotron Source (CHESS). A wide bandpass (1.7%) double-bounce multilayer monochromator supplied an intense beam of 10 keV photons. The SAXS scattering intensities were recorded with an area detector (Medoptics) with a resolution of 50 μm per pixel and a total area of about 50 mm by 50 mm. The scattering data was collected at a distance of 1888 mm and 562 mm from the sample to the detector.

### Example 7: Fabrication of Supercapacitor Devices

After carbonization, the nanoporous carbon was ground with a mortar and pestle. Electrodes were prepared by drop-casting a 50 mg/mL carbon dispersion in NMP onto a stainless steel mesh (400 mesh, Small Parts Inc.) with a diameter of 13 mm. Before the casting, the dispersion was stirred for ˜20 min and then sonicated for ˜10 min. The solid in the dispersion consisted of 85 wt % of nanoporous carbon, 5 wt % of acetylene black as a conductive additive, and 10 wt % of poly(vinylidene fluoride) as a binder. The drop-casted samples were dried on a 70° C. hot stage for 2 h and further dried in a 100° C. vacuum oven overnight. The mass of the dried electrodes was in the range of 2-4 mg. Two-electrode cells using Teflon Swagelok were built and tested. Paper filters were used as separators.

### Example 8: Electrochemical Characterization

The electrochemical properties were determined using a multichannel potentiostat/galvanostat (VMP, Biologic) in 1 M aqueous H₂SO₄ and 6 M aqueous KOH electrolyte. The cyclic voltammetry (CV) curves were obtained at various scan rates from 1 to 100 mV/s in the range of 0 to 1 V. Galvanostatic charge-discharge (CD) curves obtained at various current densities from 0.1 A/g to 10 A/g. The mass-normalized capacitance of a single electrode (C_{g}) was calculated from the Galvanostatic discharging curve according to, 1/C=1/C_{A}+1/C_{B}=1/(C_{g} m_{A})+1/(C_{g} m_{B})=1/C_{g} (1/m_{A}+1/m_{B}), thus:

$${C}_{g} = \frac{1}{Δ V ( t ) / Δ t} ( \frac{1}{{m}_{A}} + \frac{1}{{m}_{B}} ) \qquad ( 9 )$$

where m_{A} and m_{B} are the active carbon masses of the two electrodes, and I, ΔV(t), and Δt are the loading current, full discharging voltage window (1 V) including all IR drop region, and discharging time, respectively. The current density was defined as I×(1/m_{A}+1/m_{B}). Electrochemical impedance spectroscopy (EIS) measurements were performed in the frequency range of 10⁵ Hz to 10⁻³ Hz at the open circuit potential with an AC perturbation of 5 mV.

### Example 9: ORR Characterization

A glassy carbon (GC) electrode (3 mm, from Gamry) was carefully polished with 3 μm, 1 μm, and 0.25 μm diamond successively to obtain mirror-like surface. Then the electrode was washed with double distilled water and acetone and finally dried in air. 1 mg of carbon was dissolved in 1 mL solvent mixture of Nafion (5%) and EtOH (v/v=1/9) by sonication. 20 μL of the solution was dropcasted on the GC electrode surface and dried in air. All of the voltammograms were recorded at 25° C. with a Gamry Reference 600 potentiostat. Measurements were carried out at a scan rate of 10 mV/s using the as-prepared GC working electrode and a platinum disk counter electrode in N₂-saturated or O₂-saturated 0.1 M KOH aqueous solution. Potentials were recorded versus a saturated calomel electrode (SCE) reference electrode.

### Example 10: ORR Catalyzed by Binder-Free Nanocarbon Cast onto a Glassy Carbon Electrode

20 μL PAN-b-PBA copolymer (BA₇₀AN₁₂₀) DMF solution (c=10 mg/mL) was drop-cast onto a glassy carbon electrode (S=0.20 cm²). The film was dried under vacuum over night and pyrolyzed following typical conditions, i.e. (1) 280° C. under air for 1 hour and (2) 700° C. under N₂ for 30 min. The electrode was assembled to a rotator as a rotating disc electrode (RDE) for kinetic study of ORR. FIG. 8A shows the CV results in O₂ and N₂ saturated KOH aqueous solution (0.1 M). Results are presented in Table 3 which shows that factors affecting catalytic activity include conductivity, see line 1 of the table, S_{BET} (accessibility of nitrogen) see result from PAN line 3 of the table; whether the carbon was binder free (drop-casting 10 mg/mL polymer DMF solution onto GC electrode and carbonization) line 4 and N %, see result from pyrolysis at 900 C.

TABLE 3
Kinetic study of ORR by linear sweep voltammetry
(LSV) using rotating ring-disk electrode.

| | | | | | | Half-wave |
|---|---|---|---|---|---|---|
| | | | | | | potential |
| T | | Binder | S_{BET} | | | (V vs. |
| (° C.) | Sample | free? | (m²/g) | N % | n | Ag/AgCl) |
| 600 | BA₉₀AN₁₅₉ | No | 461 | 14.2 | 2.38 | −0.395 |
| 700 | BA₉₀AN₁₅₉ | No | 498 | 11.0 | 2.66 | −0.352 |
| 700 | AN₉₀ | No | 70 | 10.3 | 2.18 | −0.414 |
| 700 | BA₉₀AN₁₅₉ | Yes | 498 | 11.0 | 3.93 | −0.220 |
| 800 | BA₉₀AN₁₅₉ | No | 485 | 7.8 | 2.54 | −0.359 |
| 900 | BA₉₀AN₁₅₉ | No | 509 | 5.3 | 2.45 | −0.364 |

Conditions: 0.1M KOH aq.; Working Electrode: Glassy carbon coated with nanocarbon (binder: nafion); Counter Electrode: Pt wire; and Reference Electrode: Ag/AgCl

A second approach utilizing two novel techniques for the formation of a porour nanocarbon was also evaluated. One advance capitalizes on these developments: synthesis of low MW PAN by ICAR (only DP 50 could be used, DP 100 was too viscous when dissolved in silica-containing aq. ZnCl₂; obviously, it would be impossible to use commercial PAN). An aqueous solution of ZnCl₂ was used to form a dispersion of 8 nm silica NPs in a solution of low MW PAN (DP˜50). Then, the water was removed by freeze-drying and as-prepared composite was stabilized and pyrolyzed at 800° C. Then, silica was etched by HF (which should also remove the ZnCl₂). The electrode was prepared by dispersing 1.7 mg of the material in 1 ml of ethanol:5% Nafion solution (9:1, v/v) by sonication. 20 ul were then drop cast on a polished glassy carbon disk and left to dry. ORR was then performed in 0.1 M KOH with active material on glassy carbon disk as a working electrode, graphite counter electrode and Ag/AgCl reference. FIG. 8B shows CV scans for Ar and O2-saturated solutions recorded at 100 mV/s. A reduction wave is clearly visible under oxygen atmosphere. Onset overpotential is very low, ˜−0.1 V vs Ag/AgCl.

### Example 11: Design of a Room-Temperature Cross-Linkable Phase-Separated Block Copolymer

3-(Trimethoxysilyl)propyl methacrylate (TMSPMA) was proposed to be used as sacrificial block instead of BA with the expectation that TMSPMA side chains can be cross-linked by aqueous/acid treatment yielding a thermally stable sacrificial component which will enhance the nanostructure preservation in the carbonization process. After carbonization, the cross-linked PTMSPMA matrix can be converted to SiO₂ which then be etched away by HF treatment. The in-situ formed SiO₂ will prevent the collapse of isolated carbon domain during carbonization.

### Example 12: PAN-b-PBA HIPE

Two reactions were conducted with PBA-Br as the initiator for a SR&NI ATRP chain extension with acrylonitrile. The conditions for the first polymerization were similar to previous conditions developed for Reverse ATRP of AN HIPEs, except halogen exchange was used. The ratio of reagents were: AN:PBA:DVB:PGPR:CuCl₂:dNbpy:V-50:Water=150:1:1.2:2.4:1:75% of emulsion. The PBA-Br was dissolved in AN by sonicating for 20 minutes. The CuCl₂ and dNbpy were added to this viscous mixture and the mixture was stirred for 3 days to ensure full complexation and dissolution. During HIPE formation 4-5 mL of the aqueous phase could not be mixed into the external AN/PBA phase. This could be due to the high viscosity of the AN/PBA external phase. Reaction time was 48 hours at 60° C. The yield of the polyHIPE was 58% and the material was much spongier with a more elastic feel to it than previous pure PAN based polyHIPEs. After removing the polyHIPE from the oven large, macropores could be seen through the plastic container and SEM imaging revealed that the material was a typical porous polyHIPE material. The voids were not typical, but on the order of 1 to 5 μm, and highly interconnected. These results indicate that a PBA-Br macroinitiator can be successfully incorporated into an AN polyHIPE and polymerization occurs. The formed polyHIPEs can be stabilized and converted to carbons with macroporosity.

### Example 13: CTNCs as a Metal-Free Alternative for Photocatalytic Water Reducing Catalysts

A specified quantity of CTNC was weighed into 40 mL pre-cleaned EPA vials equipped with septa caps. The samples were then dispersed thoroughly in 7 mL of solvent via sonication for a 2 hour period. 1 mL aliquots of the photosensitizer, [Ir(ppy)₂(dtbbpy)](PF₆) in the same solvent were added to the carbon samples, followed by water and TEA. The final solutions (10 mL) contained the required amounts of photosensitizer and CTNC catalyst in an 8:1:1 solvent/water/TEA ratio. A stir bar was placed into each vial, the septa caps were screwed back on and the samples were subject to degassing by application of vacuum and subsequent back-filling with Ar. This cycle was repeated 7 times to ensure an inert atmosphere was present. After bringing the vials to atmospheric pressure, the samples were magnetically stirred for 1 hour after which they were illuminated using a home built photoreactor with side illumination (24 W 460 nm LED strip with 300 diodes, Solid Apollo SA-LS-BL-3528-300-24 V). After the specified illumination period, the vial headspace was analyzed for H₂ by gas chromatography (GOW-MAC, series 400 G/C, thermal conductivity detector, Ar carrier gas). The instrument was pre-calibrated using 10% H₂—Ar gas mixtures. To obtain H₂ evolution traces, septa caps were replaced by pressure transducers. Following the same photoreaction protocol, the pressure readings were recorded via a LabView PC interface and converted to H₂ traces post headspace quantification. The superior results of the ball milled formed CTNCs are shown in FIGS. 12A and 12B.

### Example 14: CTNCs as Catalysts for Hydrogen Evolution Reaction

A detachable glassy carbon (GC) disk insert (5 mm diameter, 4 mm thick, Pine AFED050P040GC) was carefully successively polished with 3 μm, 1 μm, and 0.25 μm diamond to obtain a mirror-like surface. The electrode was then washed with double distilled water and acetone, sonicated in water and finally dried in air. The insert was then treated under UV to remove organic residues. The as-prepared BCP was drop-cast from a 10 mg/mL solution in DIVIF onto the GC insert using a microliter syringe and dried under ambient conditions, followed by a 160° C. thermal annealing under vacuum. The annealed films were stabilized at 280° C. for 1 h under air flow (150 mL/min), purged with nitrogen gas for one hour during cooling, and then heated to the pyrolysis temperature with a heating rate of 10° C./min then pyrolyzed at temperatures ranging from 600 to 900° C. for 0.5 h under nitrogen gas flow (150 mL/min). In the discussion of the invention the electrodes prepared in this fashion are referred to as CTNC-XXX, where XXX indicates the pyrolysis temperature. The elemental composition of electrodes prepared at different temperatures is provided in Table 7. Pt/C electrode was prepared by dispersing 1 mg of a commercial Pt black in 1 mL of ethanol/Nafion solution (9:1 v/v). The dispersion was sonicated for 30 min and 20 μL were cast on a polished GC disk.

TABLE 7
Elemental composition of electrodes determined by XPS

| Composi- | CTNC- | CTNC- | CTNC- | CTNC- | C-PAN- |
|---|---|---|---|---|---|
| tion (at. %) | 600 | 700 | 800 | 900 | 800 |
| C 1s | 84.97 | 90.3 | 92.83 | 95.34 | 84.48 |
| N 1s | 11.62 | 7.22 | 4.52 | 3.05 | 9.22 |
| O 1s | 3.41 | 2.47 | 2.66 | 1.61 | 6.3 |

Electrochemical Measurements:

All of the measurements were recorded at 25° C. with a Gamry Reference 600 potentiostat. Linear sweep voltammograms were carried out at a scan rate of 20 mV/s in N₂-saturated 0.5 M H₂SO₄. The carbon-coated prepared GC insert was assembled into a rotating electrode set-up (Pine E5TQ Series) and used as the working electrode, with a graphite rod or platinum mesh as the counter electrode. All metal-free measurements were performed in a separate cell, which was not exposed to Pt. The electrode was cycled between the measurements at 100 mV/s. Potentials were recorded versus a saturated calomel electrode (SCE) reference electrode and converted to reversible hydrogen electrode (RHE) by E (RHE)=E (SCE)+0.241+0.059×pH V. CTNC electrodes cycled with graphite and platinum counter electrode are referred to as CTNC-XXXg and CTNC-XXXpt, respectively.

### Example 15: CTNCs Utilizing Low Concentrations of Deposited Pt for Hydrogen Evolution Reaction

Two sets of experiments were performed to ascertain the impact of Pt on catalytic activity: (i) cycling with a graphite counter electrode, referred to as metal-free conditions, and (ii) cycling with a Pt mesh counter electrode, referred to as Pt-cycling. In order to fully equilibrate the system, each experiment involved performing 1000 cyclic voltammetry (CV) scans, followed by recording of linear sweeping voltammograms (LSV). The electrochemical activity of CTNCs increased dramatically when the graphite counter electrode was replaced with a Pt mesh. As in the previous case, the optimum performance was observed for materials pyrolyzed under intermediate conditions (CTNC-700 pt and CTNC-800 pt), but this time it approached the performance of commercial Pt/C catalyst with much lower concentrations of Pt present on the electrode.

### Example 16: CTNCs for Metal Sequestration: Uranium Capture

The adsorption tests were conducted with a solution uranyl nitrate hexahydrate in 0.1 M NaClO₄ providing an initial [U(VI)]=100 ppm. The pH value was adjusted to 5 by the addition of HCl or NaOH solution and calibrated by a PHS-3C model meter. Adsorption experiments involved addition of 5 mg of sorbent to 5 mL of the uranyl solution followed by >24 hours mixing at T=22° C. After the adsorption process, 0.45 μm micro-pore filters were used to separate the adsorbents from the aqueous phase and the residual concentration of U(VI) solution was determined by the arsenazo III method.

Adsorption capacity Q is defined as:

$$Q = \frac{( {C}_{0} - {C}_{t} ) \times V}{M} \qquad ( 10 )$$

where C₀ and Cₜ are the initial and residual U(VI) concentration in aqueous solutions, respectively. V is the volume of the initial solution and M is the dosage of the adsorbent.

### Example 17: CTNCs as a Highly Stable Alternative to Platinum Cathodes in Dye-Sensitized Solar Cells

An organic dye of JK-306 and a hole-conducting coadsorbent of HC-A were synthesized following the same procedures as described elsewhere (ChemSusChem, 2013, 6, 1425; Chem.-Eur. J., 2011, 17, 11115). N₂ adsorption/desorption isotherms were collected using a Quantachrome Autosorb 1-C. Prior to measurement, samples were degassed at 300° C. under vacuum overnight. Brunauer-Emmett-Teller (BET) surface areas were determined from N₂ adsorption isotherms at 77 K. Multipoint BET measurements were performed at relative pressures (P/P0) in the range of 0.05-0.20. XPS measurements were performed with a Kratos Axis Ultra spectrometer under the pressure of 10⁻⁸ torr. The monochromatic X-ray source was Al Ka (1486.6 eV) and the power was 208 W (14 kV, 20 mA). The voltage step size was 0.5 eV for surveys and 0.1 eV for high resolution. The dwell time at every step was 150 ms for surveys, 600 ms for O and C, and 2000 ms for high resolution N. Quantification was performed by applying the appropriate relative sensitivity factors (RSFs, C 1s ¼ 0.297, O 1s ¼ 0.703, N 1s ¼ 0.491) after subtracting Shirleytype background. The deconvolution into component peaks in high resolution peaks were carried out using 7:3 product of Gaussian-Lorentzian line-shape. Binding energy was corrected with reference to C 1s at 285.0 eV. All the electrochemical measurements were carried out with a VersaSTAT 3 (Version 1.31), AMETEK connected to a potentiostat under dark conditions at room temperature. The EIS spectra were acquired in the frequency range from 10⁶ Hz to 0.1 Hz, at 0 V of open circuit voltage, with an AC modulation amplitude of 10 mV. EIS data analysis was processed using the Zplot/Zview 2 software.

Fabrication of the Counter Electrode on FTO:

0.1 wt % each CTNC-series materials was dispersed in 2-propanol solution by ultrasonication for 30 min and the solution was left for 2 h to separate larger particles by sedimentation. The resulting solution was deposited directly on FTO (TEC-8, Pilkington) using an e-spray technique. First, the CTNC solution was loaded into a plastic syringe equipped with a 30-gauge stainless steel hypodermic needle. The needle was connected to a high voltage power supply (ESN-HV30). A voltage of ˜4.6 kV was applied between a metal orifice and the conducting substrate at a distance of 5 cm, and substrate temperature of 60° C. The feed rate was controlled by the syringe pump at a constant flow rate of 70 μL min⁻¹. For effective comparison, a conventional Pt CE was also prepared by deposition of ca. 20 μL/cm² of H₂PtCl₆ solution (2 mg of H₂PtCl₆ in 1 mL of ethanol), and then it was sintered at 400° C. for 15 min. To evaluate the electrocatalytic activity of sample materials, a symmetrical sandwich dummy cell was fabricated from two identical CTNC-FTO or Pt-FTO sheets, which were separated by 60 μm thick Surlyn (Solaronix, Switzerland) tape as a seal and spacer leaving 0.6×0.6 cm² active area. The cell was filled with an electrolyte solution through a hole in one FTO support which was finally closed by a Surlyn seal. The FTO sheet edges were coated by ultrasonic soldering (USS-9200, MBR Electronics) to improve electrical contacts.

Assembly of Dye-Sensitized Solar Cells:

FTO plates were cleaned in detergent solution, water, and ethanol using an ultrasonic bath. The FTO substrates were immersed in 40 mM aqueous TiCl₄ solution at 70° C. for 30 min and washed with water and ethanol. A TiO₂ colloidal paste (Dyesol, 18NR-T) was screen-printed onto FTO/glass and sintered at 500° C. for 30 min in air. The thickness of the transparent layer was measured by using an Alpha-step 250 surface stylus-type profilometer (Tencor Instruments, San Jose, Calif.), and a paste for the scattering layer containing 400 nm sized anatase particles (CCIC, PST-400C) was deposited by screen-printing and then dried for 1 h at 120° C. The TiO₂ electrodes were sintered at 500° C. for 30 min. The resulting TiO₂ electrodes were immersed in a THF/ethanol (v/v, 1/2) solution containing 0.3 mM of JK-306 sensitizer (ChemSusChem 2013, 6, 1425) and 0.3 mM of a multi-functional coadsorbent HC-A (SGT-301) (Chem. Eur. J. 2011, 17, 11115; Chem. Commun. 2012, 48, 9349; J. Mater. Chem. A 2013, 1, 3977; J. Mater. Chem. A 2013, 1, 9114) (or 0.3 mM of N719 sensitizer only) and kept at room temperature for 12 h.

The dye adsorbed TiO₂ photoanodes were assembled with CTNCs-FTO or Pt CEs using a thermal adhesive film (25 μm thick Surlyn, Du-Pont) as a spacer to produce a sandwich-type cell. The electrolyte solution was 0.22 M Co(bpy)₃(BCN4)₂, 0.05 M Co(bpy)₃(BCN₄)₃, 0.1 M LiClO₄, and 0.8 M 4-tert-butylpyridine in acetonitrile. Another iodine electrolyte solution composed of 0.6 M DMPII, 0.1 M LiI, 0.05 M I₂, and 0.5 M TBP in acetonitrile was also used for the performance test of N719-based DSSCs. Electrolyte solution was introduced through a drilled hole on the CE via vacuum backfilling. The hole was sealed with cover glass using a Surlyn seal. Photoelectrochemical data were measured using a 1000 W xenon light source (Oriel, 91193) that was focused to give 100 mW cm⁻², which is the equivalent of one sun at Air Mass (AM) 1.5 G at the surface of the test cell. The light intensity was adjusted with a Si solar cell that was doubled-checked with an NREL calibrated Si solar cell (PV Measurement Inc.). The applied potential and measured cell current were measured using a Keithley model 2400 digital source meter. The current-voltage characteristics of the cell under these conditions were determined by biasing the cell externally and measuring the generated photocurrent. This process was fully automated using Wavemetrics software. The measurement-settling time between applying a voltage and measuring a current for the current-voltage characterization of DSSCs was fixed to 80 ms.

### Example 18: N-Doped Nanoporous Carbons Templated from Colloidal Silica Nanoparticles

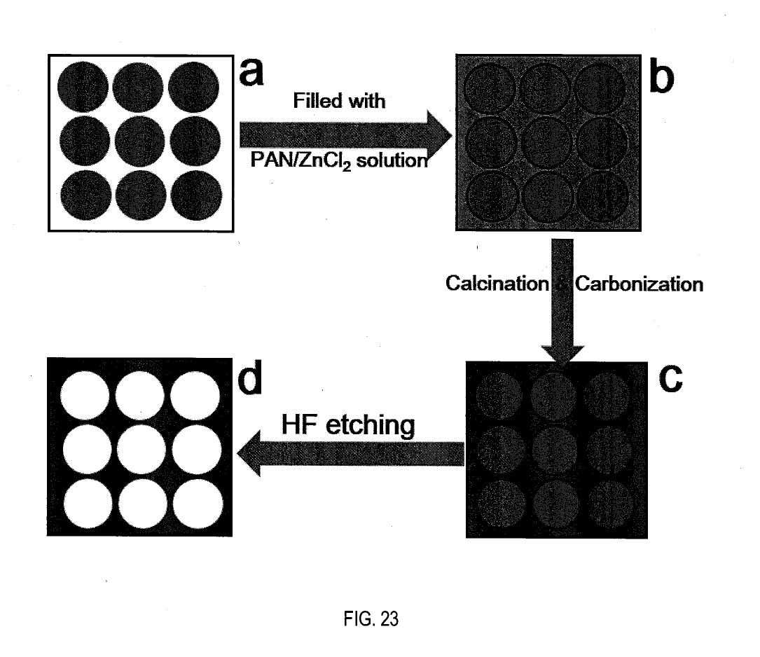

The schematic shown in FIG. 23 illustrates the basic steps and the material produced after each step. (a) colloidal silica aqueous suspension, (b) colloidal silica suspension in presence of PAN/ZnCl₂ aqueous solution, (c) freeze drying of PAN/silica composite material and carbonization, and (d) silica etching by HF solution forming nanoporous carbon.

PANs with two different DP were selected to fill the interval void between the silica nanoparticles. PAN/ZnCl₂ solution (60 wt %) of DP 100 and DP 50 were prepared and added to Ludox SM-30 silica nanoparticles. However the PAN with a DP=100 cannot be dissolved completely and formed opaque solution with a very high viscosity. Whereas the PAN with DP50 formed transparent solution indicating that lower DP can be dissolved completely in an aqueous ZnCl₂ solution. The complete dissolution of PAN and operable viscosity of final composite solution are very important prerequisite for the preparation of nanocarbon materials when regarding using silica as template and PAN as carbon source. The BET specific surface area of the nanoporous carbon was equal to 1218 m²/g, and the total pore volume was equal to 2.11 cm³/g, which is quite high for nanoporous carbon material. The pores exhibited quite narrow size distribution and the peak on the pore size distribution (PSD) was centered at about 7.7 nm, which is in a good agreement with the results assessed from TEM.

### ASPECTS OF THE INVENTION

Aspects of the invention include, but are not limited to, the following numbered clauses.

1. A functional nano-structured carbon material having heteroatoms on the edges of nano-graphitic sheets, accessible on the surface of the nano-structured carbon materials, wherein the nano-structured carbon materials are formed by pyrolysis of a supramolecular template comprising a phase separated precursor, wherein one phase is the precursor of the carbon, and the other phase is a sacrificial phase.

2. The functional nano-structured carbon material of clause 1, wherein the conditions employed during the pyrolysis control the number, position, and chemical nature of the heteroatoms, and the edge-availability of non-bonding π-electrons, in the carbonized material.

3. The functional nano-structured carbon material of clause 1 or clause 2, wherein the nano-structured carbon materials are nano-porous carbon materials having heteroatoms on the edges of nanographitic sheets accessible on the surface of the carbon.

4. The functional nano-structured carbon material of any one of clauses 1-3, wherein the phase separated precursor is a phase separated segmented copolymer, and wherein the precursor of the carbon material is carbonized at a temperature between 500° C. and 1000° C. over a time frame between 0.25 h. and 5 h.

5. The functional nano-structured carbon material of any one of clauses 1-4, wherein the phase separated precursor is a hybrid composite further comprising an inorganic phase, and wherein the precursor of the carbon material is carbonized at a temperature between 500° C. and 1000° C. over a time frame between 0.25 h. and 5 h.

6. The functional nano-structured carbon material of any one of clauses 1-5, wherein the materials comprise nanopores, mesopores, micropores, or macropores, or combinations of any thereof.

7. The functional nano-structured carbon material of clause 6, wherein the pores formed from the sacrificial organic phase have a size from ranging from 5 to 100 nm.

8. The functional nano-structured carbon material of clause 6, wherein the macropores are incorporated by addition of a non-solvent or a sacrificial solid into the supramolecular template either prior to formation of the supramolecular template or after formation of the supramolecular template.

9. The functional nano-structured carbon material of any one of clauses 1-8, wherein the heteroatoms comprise nitrogen, oxygen, phosphorous, or sulfur, or combinations of any thereof.

10. The functional nano-structured carbon material of any one of clauses 1-9, wherein the heteroatoms on the edges of the nano-graphitic sheets are exposed on the accessible surfaces of the carbons, which in combination with the non-bonding character of then-electrons along zigzag edges, endow the materials with the ability to effectively participate in a wide range of processes relying on charge transfer and/or formation of coordination bonds, such as, for example, faradaic processes enhancing charge storage density in supercapacitors, electrochemical processes for improving power density and cyclability in lithium batteries, electrocatalysis and photocatalysis of industrially and environmentally important reactions such as oxygen reduction reaction (ORR), CO₂ reduction, substrates for sequestration of metals or solvents, metal catalyst supports for heterogenous catalysis, CO₂ capture, water reduction, hydrogen evolution reactions, or cathodes for dye-sensitized solar cells.

11. The functional nano-structured carbon material of any one of clauses 1-10, wherein the activity of the nano-structured carbon is enhanced by grinding or ball milling the first formed nano-structured carbon.

12. The functional nano-porous carbon material of any one of clauses 1-11, wherein the full width at the half maximum of the N 1s peak in the X-ray photoelectron spectrum of pyridinic nitrogens in pyrolytic carbons derived from PAN is less than 2 eV.

13. The functional nano-porous carbon material of clause 12, wherein the N is peak is less than 1.75 eV.

14. The functional nano-porous carbon material of any one of clauses 1-13, wherein the phase separated segmented copolymer is thermally or chemically stabilized prior to pyrolysis.

15. The functional nano-porous carbon material of clause 14, wherein the phase separated segmented copolymer is thermally or chemically stabilized at a temperature below 300° C.

16. The functional nano-porous carbon material of clause 14 or clause 15, wherein the stabilization process is conducted in a controlled environment.

17. The functional nano-porous carbon material of any one of clauses 15-17, wherein the thermal stabilization process is conducted in an oxidizing atmosphere.

18. The functional nano-porous carbon material of clause 17, wherein the oxidizing atmosphere comprises reduced levels of oxygen.

19. The functional nano-porous carbon material of any one of clauses 1-18, wherein the carbon precursor phase comprises a discontinuous phase which is thermally or chemically stabilized before carbon pyrolysis, and the precursor phase forms individual nano-structured carbons after pyrolysis.

20. The functional nano-porous carbon material of any one of clauses 1-19, wherein the carbon precursor phase comprises a continuous phase which is thermally or chemically stabilized before carbon pyrolysis, and the precursor phase forms porous carbons after pyrolysis.

21. The functional nano-porous carbon material of any one of clauses 1-20, wherein the pyrolysis is conducted under a reduced oxygen or non-oxygen contain atmosphere further comprising nitrogen, carbon dioxide, ammonia, steam, or chlorine, or combinations of any thereof.

22. The functional nano-porous carbon material of any one of clauses 1-21, wherein the incorporated heteroatom functions as a stabilizer to hold a metal to the surface of the carbon, or functions as a ligand that provides additional activity in heterogeneous catalysis applications.

### INCORPORATION BY REFERENCE

The following documents are incorporated by reference into this specification.
1. McEnaney, B., Structure and bonding in carbon material. In Carbon Materials for Advanced Technologies, Buchell, T. D., Ed. Pergamon, Amsterdam, 1999; pp 1-33.
2. Whittaker, A. G.; Kintner, P. L. Carbon 1985, 23, 255-262.
3. Kinoshita, K., Carbon: electrochemical and physicochemical properties. Wiley: New York, 1988.
4. Pesin, L. A. Structure and properties of glass-like carbon. J. Mater. Sci. 2002, 37, 1-28.
5. Jenkins, G. M.; Kawamura, K. Structure of Glassy Carbon. Nature 1971, 231, 175-6.
6. Elias, D. C, et al.; Control of Graphene's Properties by Reversible Hydrogenation: Evidence for Graphane. Science 2009, 323, 610-613.
7. Geim, A. K. Graphene: Status and Prospects. Science 2009, 324, 1530-1534.
8. Rao, C. N. R.; et al.; Graphene: The New Two-Dimensional Nanomaterial. Angew. Chem. Int. Ed. 2009, 48, 7752-7777.
9. Rao, C. N. R.; et al.; Graphene, the new nanocarbon. J. Mater. Chem. 2009, 19, 2457-2469.
10. Allen, M. J.; Tung, V. C.; Kaner, R. B. Honeycomb Carbon: A Review of Graphene. Chem. Rev. 2009, 110, 132-145.
11. Novoselov, K. S.; Jiang, Z.; Zhang, Y.; Morozov, S. V.; Stormer, H. L.; Zeitler, U.; Maan, J. C.; Boebinger, G. S.; Kim, P.; Geim, A. K. Room-temperature quantum hall effect in graphene. Science 2007, 315, 1379-1379.
12. Nakada, K.; Fujita, M.; Dresselhaus, G.; Dresselhaus, M. S. Edge state in graphene ribbons: Nanometer size effect and edge shape dependence. Phys. Rev. B 1996, 54, 17954-17961.
13. Schulz, M. F., Bates, F. S, Morphology of block copolymers; Physical Properties of Polymers Handbook, 1996; pp 427-433.
14. Jenkins, A. D., R. G. Jones, et al. “Terminology for reversible-deactivation radical polymerization previously called “controlled” radical or “living” radical polymerization (IUPAC Recommendations 2010).” Pure Appl. Chem., 2010, 82(2): 483-491.
15. Matyjaszewski, K.; Xia, J. H. Atom transfer radical polymerization. Chem. Rev. 2001, 101, 2921-2990.
16. Tsarevsky, N. V.; Matyjaszewski, K. “Green” atom transfer radical polymerization: From process design to preparation of well-defined environmentally friendly polymeric materials. Chem. Rev. 2007, 107, 2270-2299.
17. Hawker, C. J.; Bosman, A. W.; Harth, E.; New Polymer Synthesis by Nitroxide Mediated Living Radical Polymerizations; Chemical Reviews 2001, 101, 3661-3688.
18. Moad, G.; Rizzardo, E.; Thang, S. H.; Living Radical Polymerization by the RAFT Process—A Second Update; Aust. J. Chem. 2009, 62, 1402-1472.
19. Kowalewski, T.; Tsarevsky, N. V.; Matyjaszewski, K.; Nanostructured Carbon Arrays from Block Copolymers of Polyacrylonitrile Journal of the American Chemical Society 2002, 124, 10632-10633.
20. Wu, D.; Nese, A.; Pietrasik, J.; Liang, Y.; He, H.; Kruk, M.; Huang, L.; Kowalewski, T.; Matyjaszewski, K. Preparation of Polymeric Nanoscale Networks from Cylindrical Molecular Bottlebrushes; ACS Nano 2012, 6, 6208-6214.
21. Wu, D.; Dong, H.; Pietrasik, J.; Kim, E. K.; Hui, C. M.; Zhong, M.; Jaroniec, M.; Kowalewski, T.; Matyjaszewski, K.: Novel Nanoporous Carbons from Well-Defined Poly(styrene-co-acrylonitrile)-Grafted Silica Nanoparticles Chem. Mater. 2011, 23, 2024-2026.
22. Tang, C. B et al.; Long-range ordered thin films of block copolymers prepared by zone-casting and their thermal conversion into ordered nanostructured carbon. J. Am. Chem. Soc. 2005, 127, 6918-6919;
23. Zhong, M.; et al.; Electrochemically Active Nitrogen-Enriched Nanocarbons with Well-Defined Morphology Synthesized by Pyrolysis of Self-Assembled Block Copolymer. J. Am. Chem. Soc. 2012, 134, 14846-14857.
24. McGann, J. P.; et al.; Block Copolymer Templating as a Path to Porous Nanostructured Carbons with Highly Accessible Nitrogens for Enhanced (Electro)chemical Performance. Macromol. Chem. Phys. 2012, 213, 1078-1090.
25. Zhong, M.; et al.; Copolymer-templated nitrogen-enriched porous nanocarbons for CO2 capture. Chem. Commun. 2012, 48, 11516-11518.
26. Kowalewski, T.; Tsarevsky, N. V.; Matyjaszewski, K. Nanostructured carbon arrays from block copolymers of polyacrylonitrile. J. Am. Chem. Soc. 2002, 124, 10632-10633
27. Tang, C. B.; Tracz, A.; Kruk, M.; Zhang, R.; Smilgies, D. M.; Matyjaszewski, K.; Kowalewski, T. Long-range ordered thin films of block copolymers prepared by zone-casting and their thermal conversion into ordered nanostructured carbon. J. Am. Chem. Soc. 2005, 127, 6918-6919.
28. Dingcai Wu, Fei Xu, Bin Sun, Ruowen Fu, Hongkun He, and Krzysztof Matyjaszewski; Design and Preparation of Porous Polymers Chem. Rev., 2012, 112 (7), 3959-4015.
29. Wu, D.; Nese, A.; Pietrasik, J.; Liang, Y.; He, H.; Kruk, M.; Huang, L.; Kowalewski, T.; Preparation of Polymeric Nanoscale Networks from Cylindrical Molecular Bottlebrushes; Matyjaszewski, K. ACS Nano 2012, 6, 6208-6214.
30. Pels, J. R.; Kapteijn, F.; Moulijn, J. A.; Zhu, Q.; Thomas, K. M. Evolution of Nitrogen Functionalities in Carbonaceous Materials during Pyrolysis. Carbon 1995, 33, 1641-1653.
31. Morales, M. S.; Ogale, A. A. UV-induced crosslinking and cyclization of solution-cast polyacrylonitrile copolymer. J. Appl. Polym. Sci. 2013, 128, 2081-2088.
32. Ouyang, Q.; Cheng, L.; Wang, H.; Li, K. Mechanism and kinetics of the stabilization reactions of itaconic acid-modified polyacrylonitrile. Polym. Degrad. Stabil. 2008, 93, 1415-1421.
33. Lefevre, M.; Proietti, E.; Jaouen, F.; Dodelet, J. P. Iron-Based Catalysts with Improved Oxygen Reduction Activity in Polymer Electrolyte Fuel Cells. Science 2009, 324, 71-74.
34. Wu, G.; More, K. L.; Johnston, C. M.; Zelenay, P. High-Performance Electrocatalysts for Oxygen Reduction Derived from Polyaniline, Iron, and Cobalt. Science 2011, 332, 443-447.
35. Yang, S.; Feng, X.; Wang, X.; Müllen, K. Graphene-Based Carbon Nitride Nanosheets as Efficient Metal-Free Electrocatalysts for Oxygen Reduction Reactions. Angewandte Chemie International Edition 2011, 50, 5339-5343.
36. Tanaka A. A.; Fierro C., Scherson D., and E. B. Yeager Electrocatalytic Aspects of Iron Phthalocyanine and Its μ-Oxo Derivatives Dispersed on High Surface Area Carbon. J. Phys. Chem. 1987, 91, 3799
37. Balaban, A. T. Aromaticity of Six-Membered Rings with One Heteroatom. Topics in Heterocyclic Chemistry 2009, 19, 203-246.
38. Barton, E. E.; Rampulla, D. M.; Bocarsly, A. B. Selective solar-driven reduction of CO₂ to methanol using a catalyzed p-GaP based photoelectrochemical cell. J Am. Chem. Soc. 2008, 130, 6342-6344.
39. Cole, E. B.; Lakkaraju, P. S.; Rampulla, D. M.; Morris, A. J.; Abelev, E.; Bocarsly, A. B. Using a One-Electron Shuttle for the Multielectron Reduction of CO2 to Methanol: Kinetic, Mechanistic, and Structural Insights. J Am. Chem. Soc. 2010, 132, 11539-11551.
40. Zhang, Y. J.; Mori, T.; Ye, J. H.; Antonietti, M. Phosphorus-Doped Carbon Nitride Solid: Enhanced Electrical Conductivity and Photocurrent Generation. J Am Chem Soc 2010, 132, 6294.
41. Liu, Z. W.; Peng, F.; Wang, H. J.; Yu, H.; Zheng, W. X.; Yang, J. A. Phosphorus-Doped Graphite Layers with High Electrocatalytic Activity for the O(2) Reduction in an Alkaline Medium. Angew Chem Int Edit 2011, 50, 3257-3261.
42. Tavakkoli M, Kallio T, Reynaud O, Nasibulin A G, Johans C, Sainio J, Jiang H, Kauppinen E I, Laasonen K.; Single-shell carbon-encapsulated iron nanoparticles: synthesis and high electrocatalytic activity for hydrogen evolution reaction. Angew. Chem. Int. Ed. 2015, 54, 4535-4538.
43. Zhang, H.; Jiang F.; Zhou, R.; Du, Y.; Yang, P.; Wang, C.; Xu, J.; Effect of deposition potential on the structure and electrocatalytic behavior of Pt micro/nanoparticles. Int. J. Hydrogen Energy 2011, 36, 15052-15059.
44. Yue, Y.; Zhang, C.; Tang, Q.; Mayes, R. T.; Liao, W.-P.; Liao, C.; Tsouris, C.; Stankovich, J. J.; Chen, J.; Hensley, D. K.; Abney, C. W.; Jiang, D.-e.; Brown, S.; Dai, S. A Poly(acrylonitrile)-Functionalized Porous Aromatic Framework Synthesized by Atom-Transfer Radical Polymerization for the Extraction of Uranium from Seawater Industrial & Engineering Chemistry Research, Ind. Eng. Chem. Res., 2016, 55 (15), pp 4125-4129.
45. Brown, S.; Chatterjee, S.; Li, M.; Yue, Y.; Tsouris, C.; Janke, C. J.; Saito, T.; Dai, S. Uranium Adsorbent Fibers Prepared by Atom-Transfer Radical Polymerization from Chlorinated Polypropylene and Polyethylene Trunk Fibers; Ind. Eng. Chem. Res., 2016, 55 (15), pp 4130-4135.
46. Tomonori Saito, Suree Brown, Sabornie Chatterjee, Jungseung Kim, Costas Tsouris, Richard T. Mayes, Li-Jung Kuo, Gary Gill, Yatsandra Oyola, Christopher J. Janke, Sheng Dai. Uranium recovery from seawater: development of fiber adsorbents prepared viaatom-transfer radical polymerization. J. Mater. Chem. A, 2014, 2, 14674-14681.
47. Song, Y.; Ye, G.; Lu, Y.; Chen, J.; Wang, J.; Matyjaszewski, K. Surface-Initiated ARGET ATRP of Poly(Glycidyl Methacrylate) from Carbon Nanotubes via Bioinspired Catechol Chemistry for Efficient Adsorption of Uranium Ions, ACS Macro Letters 2016, 5, 382-386.
48. Kruk, M.; Jaroniec, M.; Gas Adsorption Characterization of Ordered Organic-Inorganic Nanocomposite Materials. Chem. Mater. 2001, 13, 3169-3183.
49. Kruk, M.; Jaroniec, M.; Gadkaree, K. P.; Nitrogen Adsorption Studies of Novel Synthetic Active Carbons; J. Colloid. Interface Sci. 1997, 192, 250-256.
50. Kruk, M.; Jaroniec, M.; Sayari, A. Application of Large Pore MCM-41 Molecular Sieves To Improve Pore Size Analysis Using Nitrogen Adsorption Measurements. Langmuir 1997, 13, 6267-6273.
51. Barrett, E. P.; Joyner, L. G.; Halenda, P. P. The Determination of Pore Volume and Area Distributions in Porous Substances. I. Computations from Nitrogen Isotherms. J. Am. Chem. Soc. 1951, 73, 373-380.
52. Lim K, Ju M J, Song J, Choi I T, Do K, Choi H, Song K, Kim H K, Ko J.; Organic sensitizers featuring a planar indeno[1,2-b]-thiophene for efficient dye-sensitized solar cells. ChemSusChem, 2013, 6, 1425.
53. Bok Joo Song, Hae Min Song, In Taek Choi, Sang Kyun Kim, Kang Duk Seo, Min Soo Kang, Myung Jun Lee, Dae Won Cho, Myung Jong Ju, Hwan Kyu Kim; A Desirable Hole-Conducting Coadsorbent for Highly Efficient Dye-Sensitized Solar Cells through an Organic Redox Cascade Strategy. Chem. A Eur. J., 2011, 17, 11115.
54. Min Soo Kang, Sung Ho Kang, Sang Gyun Kim, In Taek Choi, Jung Ho Ryu, Myung Jong Ju, Daeheum Cho, Jin Yong Lee and Hwan Kyu Kim; Novel D-π-A structured Zn(II)-porphyrin dyes containing a bis(3,3-dimethylfluorenyl)amine moiety for dye-sensitised solar cells. Chem. Commun. 2012, 48, 9349
55. Chunping Chen, Penghua Wang, Teik-Thye Lim, Lihong Liu, Shaomin Liu, Rong Xu.; A facile synthesis of monodispersed hierarchical layered double hydroxide on silica spheres for efficient removal of pharmaceuticals from water. J. Mater. Chem. A 2013, 1, 3977.
56. In Taek Choi, Myung Jong Ju, Sung Ho Kang, Min Soo Kang, Ban Seok You, Ji Yeoun Hong, Yu Kyung Eom, Sang Hyun Song and Hwan Kyu Kim; Structural effect of carbazole-based coadsorbents on the photovoltaic performance of organic dye-sensitized solar cells. J. Mater. Chem. A, 2013, 1, 9114-9121

Various features and characteristics of the invention(s) are described in this specification and illustrated in the drawings to provide an understanding of the function, operation, composition, structure, and/or manufacture of the disclosed processes, methods, and compositions. It is understood that the various features and characteristics of the inventions(s) described in this specification and illustrated in the drawings can be combined in any suitable manner, regardless of whether such features and characteristics are expressly described or illustrated in combination in this specification. The Inventors and the Applicant expressly intend such combinations of features and characteristics to be included within the scope of the invention(s) described in this specification. As such, the claims can be amended to recite, in any combination, any features and characteristics expressly or inherently described in, or otherwise expressly or inherently supported by, this specification, including features and characteristics illustrated in the drawings. Furthermore, the Applicant reserves the right to amend the claims to affirmatively disclaim features and characteristics that may be present in the prior art, even if those features and characteristics are not expressly described in this specification. Therefore, any such amendments will not add new matter to the specification or claims, and will comply with the written description requirement under 35 U.S.C. §112(a).

Also, any numerical range recited in this specification describes all sub-ranges of the same numerical precision (i.e., having the same number of specified digits) subsumed within the recited range. For example, a recited range of “1.0 to 10.0” describes all sub-ranges between (and including) the recited minimum value of 1.0 and the recited maximum value of 10.0, such as, for example, “2.4 to 7.6,” even if the range of “2.4 to 7.6” is not expressly recited in the text of the specification. Accordingly, the Applicant reserves the right to amend this specification, including the claims, to expressly recite any sub-range of the same numerical precision subsumed within the ranges expressly recited in this specification. All such ranges are inherently described in this specification such that amending to expressly recite any such sub-ranges will comply with the written description requirement under 35 U.S.C. §112(a). Additionally, numerical parameters described in this specification should be construed in light of the number of reported significant digits, numerical precision, and by applying ordinary rounding techniques. It is also understood that numerical parameters described in this specification will necessarily possess the inherent variability characteristic of the underlying measurement techniques used to determine the numerical value of the parameter.

The invention(s) described in this specification can comprise, consist of, or consist essentially of the various features and characteristics described in this specification. The terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. Thus, a process, method, or composition that “comprises,” “has,” “includes,” or “contains” one or more features and/or characteristics possesses those one or more features and/or characteristics, but is not limited to possessing only those one or more features and/or characteristics. Likewise, an element of a process, method, or composition that “comprises,” “has,” “includes,” or “contains” one or more features and/or characteristics possesses those one or more features and/or characteristics, but is not limited to possessing only those one or more features and/or characteristics, and may possess additional features and/or characteristics.

The grammatical articles “one”, “a”, “an”, and “the”, as used in this specification, are intended to include “at least one” or “one or more”, unless otherwise indicated. Thus, the articles are used in this specification to refer to one or more than one (i.e., to “at least one”) of the grammatical objects of the article. By way of example, “a component” means one or more components, and thus, possibly, more than one component is contemplated and can be employed or used in an implementation of the described processes, compositions, and products. Further, the use of a singular noun includes the plural, and the use of a plural noun includes the singular, unless the context of the usage requires otherwise.

Any patent, publication, or other document identified in this specification is incorporated by reference into this specification in its entirety unless otherwise indicated, but only to the extent that the incorporated material does not conflict with existing descriptions, definitions, statements, illustrations, or other disclosure material expressly set forth in this specification. As such, and to the extent necessary, the express disclosure as set forth in this specification supersedes any conflicting material incorporated by reference. Any material, or portion thereof, that is incorporated by reference into this specification, but which conflicts with existing definitions, statements, or other disclosure material set forth herein, is only incorporated to the extent that no conflict arises between that incorporated material and the existing disclosure material. Applicant reserves the right to amend this specification to expressly recite any subject matter, or portion thereof, incorporated by reference. The amendment of this specification to add such incorporated subject matter will comply with the written description requirement under 35 U.S.C. §112(a).

1. A process for producing a carbon nanomaterial comprising:
forming a phase separated (co)polymer having a carbon precursor phase and a sacrificial phase, wherein the carbon precursor phase comprises a (co)polymer comprising covalently bonded nitrogen atoms;
chemically or thermally removing the sacrificial phase from the phase separated (co)polymer; and
heating the (co)polymer comprising the carbon precursor phase at a temperature of 500-1,000° C., thereby pyrolyzing the (co)polymer comprising the carbon precursor phase and converting the (co)polymer comprising the carbon precursor phase into a carbon nanomaterial comprising nitrogen-doped nanographene structures having edge-on topology to an outer surface of the carbon nanomaterial or to a surface of a pore in the carbon nanomaterial, wherein the nanographene structures comprise nitrogen atoms located along the edges of the nanographene sheets bordering the outer surface of the carbon nanomaterial or the surface of a pore in the carbon nanomaterial.

2. The process for producing a carbon nanomaterial of claim 1, further comprising heating the (co)polymer comprising the carbon precursor phase in an oxidizing atmosphere at a temperature of 200-300° C., and thereafter heating the (co)polymer comprising the carbon precursor phase at a temperature of 500-1,000° C. to pyrolyze the (co)polymer comprising the carbon precursor phase.

3. The process for producing a carbon nanomaterial of claim 1, further comprising grinding or milling the carbon nanomaterial into a powder.

4. The process for producing a carbon nanomaterial of claim 3, wherein the carbon nanomaterial is ground or milled into a powder having a particle size of 1-100 nanometers.

5. The process for producing a carbon nanomaterial of claim 1, wherein the (co)polymer comprising the carbon precursor phase is heated at a temperature of 600-800° C. to pyrolyze the (co)polymer comprising the carbon precursor phase.

6. The process for producing a carbon nanomaterial of claim 1, wherein the (co)polymer comprising the carbon precursor phase is heated at a temperature of 500-1,000° C. for 0.25-5 hours to pyrolyze the (co)polymer comprising the carbon precursor phase.

7. The process for producing a carbon nanomaterial of claim 1, wherein the (co)polymer comprising the carbon precursor phase is heated at a temperature of 500-1,000° C. for 0.5-3 hours to pyrolyze the (co)polymer comprising the carbon precursor phase.

8. The process for producing a carbon nanomaterial of claim 1, wherein the (co)polymer comprising the carbon precursor phase is heated at a temperature of 500-1,000° C. in an inert atmosphere to pyrolyze the (co)polymer comprising the carbon precursor phase.

9. The process for producing a carbon nanomaterial of claim 1, wherein the (co)polymer comprising the carbon precursor phase is heated at a temperature of 500-1,000° C. in an activating atmosphere comprising N₂, CO₂, O₂, steam, chlorine, or ammonia, or a combination of any thereof, to pyrolyze the (co)polymer comprising the carbon precursor phase.

10. The process for producing a carbon nanomaterial of claim 1, wherein the nanographene structures comprise pyridinic nitrogen atoms located along the edges of the nanographene sheets.

11. The process for producing a carbon nanomaterial of claim 10, wherein the full width at the half maximum of the N 1s peak in the X-ray photoelectron spectrum of the pyridinic nitrogens is less than 2 eV.

12. The process for producing a carbon nanomaterial of claim 11, wherein the full width at the half maximum of the N 1s peak in the X-ray photoelectron spectrum of the pyridinic nitrogens is less than 1.75 eV.

13. The process for producing a carbon nanomaterial of claim 1, wherein carbon precursor phase comprises a polymer block formed from acrylonitrile monomer units, vinyl acetylene monomer units, 4-vinyl pyridine monomer units, styrene monomer units, or combinations thereof.

14. The process for producing a carbon nanomaterial of claim 1, wherein carbon precursor phase comprises a polyacrylonitrile block.

15. The process for producing a carbon nanomaterial of claim 1, wherein the sacrificial phase is thermally removed from the phase separated (co)polymer by simultaneously heating the sacrificial phase and the carbon precursor phase at a temperature of 500-1,000° C.

16. The process for producing a carbon nanomaterial of claim 1, wherein forming the phase separated (co)polymer having the carbon precursor phase and the sacrificial phase comprises forming a hybrid composite further comprising an inorganic phase.

17. The process for producing a carbon nanomaterial of claim 1, wherein the carbon precursor phase comprises a discontinuous phase that forms separated carbon nanomaterial structures after pyrolysis.

18. The process for producing a carbon nanomaterial of claim 1, wherein the carbon precursor phase comprises a continuous phase that forms a porous carbon nanomaterial after pyrolysis.

19. The process for producing a carbon nanomaterial of claim 18, wherein the pores are formed from the volume occupied by the removed sacrificial phase and have a size from 5-100 nm.

20. The process for producing a carbon nanomaterial of claim 1, wherein the carbon nanomaterial comprises nanopores, mesopores, micropores, or macropores, or a combination of any thereof, and wherein nitrogen-doped nanographene structures have edge-on topology to the surfaces of the pore in the carbon nanomaterial.

21. A process for producing a carbon nanomaterial comprising:
forming a phase separated (co)polymer having a carbon precursor phase and a sacrificial phase, wherein the carbon precursor phase comprises a (co)polymer comprising covalently bonded heteroatoms;
chemically or thermally removing the sacrificial phase from the phase separated (co)polymer; and
heating the (co)polymer comprising the carbon precursor phase at a temperature of 500-1,000° C., thereby pyrolyzing the (co)polymer comprising the carbon precursor phase and converting the (co)polymer comprising the carbon precursor phase into a carbon nanomaterial comprising heteroatom-doped nanographene structures having edge-on topology to an outer surface of the carbon nanomaterial or to a surface of a pore in the carbon nanomaterial, wherein the nanographene structures comprise heteroatoms located along the edges of the nanographene sheets bordering the outer surface of the carbon nanomaterial or the surface of a pore in the carbon nanomaterial.

22. The process for producing a carbon nanomaterial of claim 19, wherein the heteroatoms comprise nitrogen, oxygen, phosphorous, or sulfur, or a combination of any thereof.
